(19) United States
(12) Patent Application Publication
(10) Pub. No.: US 2026/0293395 A1
(43) Pub. Date: Sep. 24, 2026

(54) DISPLAY DEVICE AND ELECTRONIC APPARATUS INCLUDING THE SAME

(71) Applicant: Samsung Display Co., Ltd., Yongin-si (KR)

(72) Inventors: Myunghee Han, Yongin-si (KR); Sangwoo Kim, Yongin-si (KR); Hosik Shin, Yongin-si (KR); Hyejin Joo, Yongin-si (KR)

(21) Appl. No.: 19/556,684

(22) Filed: Mar. 4, 2026

(30) Foreign Application Priority Data
Mar. 18, 2025 (KR) 10-2025-0034884

(51) Int. Cl. H10H 29/37; H10H 29/49; H10H 29/854

(52) U.S. Cl. CPC H10H 29/37; H10H 29/49; H10H 29/854

(57) ABSTRACT

A display device includes an organic insulating layer, a light-emitting diode on the organic insulating layer, and a bank layer on a pixel electrode of the light-emitting diode and including a first layer and a second layer on the first layer. The bank layer defines therein first and second openings passing through the bank layer. The second layer of the bank layer includes a first protrusion tip extending from a point at which a lateral surface of the first layer facing the second opening meets a bottom surface of the second layer, the organic insulating layer includes a concave portion overlapping the second opening, and an inorganic layer between the organic insulating layer and the bank layer includes a second protrusion tip extending from a point at which a lateral surface of the organic insulating layer facing the concave portion meets a bottom surface of the inorganic layer.

This application claims priority to Korean Patent Application No. 10-2025-0034884, filed on Mar. 18, 2025, and all the benefits accruing therefrom under 35 U.S.C. §119, the content of which in its entirety is herein incorporated by reference.

### BACKGROUND

### 1. Field

One or more embodiments relate to a display device, and more particularly, to a display device and an electronic apparatus including the display device.

### 2. Description of the Related Art

With the development of display devices that visually display various electrical signals, various display devices having excellent characteristics such as being slim, being lightweight, having low power consumption, and the like, and electronic apparatuses including the same have been introduced. Research and development have been carried out on display devices of various structures, such as flexible display devices that may be folded or rolled into a roll shape, and stretchable display devices, and electronic apparatuses including the same.

### SUMMARY

One or more embodiments include a display device and a structure of an electronic apparatus including the display device.

Additional aspects will be set forth in part in the description which follows and, in part, will be apparent from the description, or may be learned by practice of the presented embodiments of the disclosure.

According to one or more embodiments, a display device includes: a substrate; an organic insulating layer disposed on the substrate; a light-emitting diode including a pixel electrode disposed on the organic insulating layer, an intermediate layer on the pixel electrode, and an opposite electrode on the intermediate layer; a bank layer disposed on the pixel electrode of the light-emitting diode, the bank layer including a first layer including metal and a second layer disposed on the first layer; and an inorganic layer disposed between the organic insulating layer and the bank layer, where the bank layer defines therein a first opening and a second opening passing through the first layer and the second layer of the bank layer, the first opening overlaps the pixel electrode in a plan view, and the second opening at least partially surrounds the first opening in the plan view, where the second layer of the bank layer includes a first protrusion tip extending from a point at which a lateral surface of the first layer facing the second opening meets a bottom surface of the second layer, where the organic insulating layer defines therein a concave portion overlapping the second opening in the plan view, and where the inorganic layer includes a second protrusion tip extending from a point at which a lateral surface of the organic insulating layer facing the concave portion meets a bottom surface of the inorganic layer.

A length of the second protrusion tip may be less than a length of the first protrusion tip.

The display device may further include a dummy opposite electrode including the same material as the opposite electrode, where the opposite electrode may be disposed in the first opening of the bank layer and be in direct contact with the first layer of the bank layer, and where the dummy opposite electrode may be in direct contact with the first layer of the bank layer while continuously extending within the second opening of the bank layer.

The display device may further include a dummy intermediate layer including the same material as the intermediate layer, where a portion of the dummy intermediate layer may be in the concave portion of the organic insulating layer and be covered by the dummy opposite electrode.

The second layer of the bank layer may include a third protrusion tip extending from a point at which a lateral surface of the first layer facing the first opening meets the bottom surface of the second layer.

The inorganic layer may include an insulating inorganic material.

The inorganic layer may include a conductive inorganic material, and the first layer of the bank layer may be in direct contact with the conductive inorganic material.

The second layer of the bank layer may include an inorganic material.

The display device may further include an encapsulation layer disposed on the light-emitting diode, where the encapsulation layer may include an inorganic encapsulation layer including an inorganic insulating material, and the inorganic encapsulation layer may cover an upper surface and a lower surface of the first protrusion tip, and an upper surface and a lower surface of the second protrusion tip.

A depth of the concave portion may be less than a thickness of the first layer of the bank layer, and less than a thickness of the organic insulating layer.

According to one or more embodiments, an electronic apparatus includes a display device configured to display an image, where the display device includes: a substrate; an organic insulating layer disposed on the substrate; a light-emitting diode including a pixel electrode disposed on the organic insulating layer, an intermediate layer on the pixel electrode, and an opposite electrode on the intermediate layer; a bank layer disposed on the pixel electrode of the light-emitting diode, the bank layer including a first layer including metal and a second layer disposed on the first layer; and an inorganic layer disposed between the organic insulating layer and the bank layer, where the bank layer defines therein a first opening and a second opening passing through the first layer and the second layer of the bank layer, the first opening overlaps the pixel electrode in a plan view, the second opening at least partially surrounds the first opening in the plan view, where the second layer of the bank layer includes a first protrusion tip extending from a point at which a lateral surface of the first layer facing the second opening meets a bottom surface of the second layer, where the organic insulating layer defines therein a concave portion overlapping the second opening in the plan view, and where the inorganic layer includes a second protrusion tip extending from a point at which a lateral surface of the organic insulating layer facing the concave portion meets a bottom surface of the inorganic layer.

A depth of the concave portion may be less than a thickness of first layer of the bank layer and less than a thickness of the organic insulating layer, and a length of the second protrusion tip may be less than a length of the first protrusion tip.

The display device may further include a dummy opposite electrode including the same material as the opposite electrode, where the opposite electrode may be disposed in the first opening of the bank layer and be in direct contact with the first layer of the bank layer, and where the dummy opposite electrode may be in direct contact with the first layer of the bank layer while continuously extending within the second opening of the bank layer.

The display device may further include a dummy intermediate layer including the same material as the intermediate layer, where a portion of the dummy intermediate layer may be present in the concave portion of the organic insulating layer and be covered by the dummy opposite electrode.

The second layer of the bank layer may include a third protrusion tip extending from a point at which a lateral surface of the first layer facing the first opening meets the bottom surface of the second layer.

The inorganic layer may include an insulating inorganic material.

The inorganic layer may include a conductive inorganic material, and the first layer of the bank layer may be in direct contact with the conductive inorganic material.

The second layer of the bank layer may include an inorganic material.

The display device may further include an encapsulation layer disposed on the light-emitting diode.

The encapsulation layer may include an inorganic encapsulation layer including an inorganic insulating material, and the inorganic encapsulation layer may cover an upper surface and a lower surface of the first protrusion tip, and an upper surface and a lower surface of the second protrusion tip.

The electronic apparatus may further include strokes disposed on a rear surface of the display device and configured to induce three-dimensional deformation of the display device.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view of a display device according to an embodiment;

FIGS. 2A and 2B are perspective views of the display device of FIG. 1 in a state of being stretched in a first direction;

FIG. 2C is a perspective view of the display device of FIG. 1 in a state of being stretched in a second direction;

FIG. 2D is a perspective view of the display device of FIG. 1 in a state of being stretched in the first direction and the second direction;

FIG. 2E is a perspective view of the display device of FIG. 1 in a state of being stretched in a third direction;

FIG. 3 is a schematic plan view of a display device according to an embodiment.

FIG. 4A is an enlarged plan view of a portion of a display device, showing a portion IV of FIG. 3, according to an embodiment;

FIG. 4B is an enlarged plan view of a portion of a display device, showing a portion IV of FIG. 3, according to an embodiment;

FIG. 4C is an enlarged plan view of a portion of a display device, showing a portion IV of FIG. 3, according to an embodiment;

FIG. 4D is an enlarged plan view of a portion of a display device, showing a display area DA of FIG. 3, according to an embodiment;

FIG. 5 is a schematic cross-sectional view of a display device according to an embodiment;

FIGS. 6A-6C are equivalent circuit diagrams of a sub-pixel of a display device according to an embodiment;

FIG. 7 is a schematic plan view of a portion of a display device, for example, a display area, according to an embodiment;

FIG. 8 is a cross-sectional view of a display device according to an embodiment;

FIG. 9 is a cross-sectional view of a display device according to an embodiment;

FIG. 10 is a cross-sectional view of a display device according to an embodiment;

FIG. 11A is a schematic perspective view of an electronic apparatus including a display device, according to an embodiment;

FIG. 11B is a schematic block diagram of an electronic apparatus including a display device, according to an embodiment; and

FIGS. 12A-12I are schematic perspective views of an electronic apparatus including a display device, according to an embodiment, respectively.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term "and/or" includes any and all combinations of one or more of the associated listed items. Throughout the disclosure, the expression "at least one of a, b, and c" indicates only a, only b, only c, both a and b, both a and c, both b and c, all of a, b, and c, or variations thereof.

As the disclosure allows for various changes and numerous embodiments, certain embodiments will be illustrated in the drawings and described in the written description. Effects and features of the disclosure, and methods for achieving them will be clarified with reference to embodiments described below in detail with reference to the drawings. However, the disclosure is not limited to the following embodiments and may be embodied in various forms.

Hereinafter, embodiments will be described with reference to the accompanying drawings, wherein like reference numerals refer to like elements throughout and a repeated description thereof is omitted.

While such terms as "first" and "second" may be used to describe various elements, such elements must not be limited to the above terms. The above terms are used to distinguish one element from another.

The singular forms "a," "an," and "the" as used herein are intended to include the plural forms as well unless the context clearly indicates otherwise.

It will be understood that the terms "comprise," "comprising," "include" and/or "including" as used herein specify the presence of stated features or elements but do not preclude the addition of one or more other features or elements.

It will be further understood that, when a layer, region, or element is referred to as being "on" another layer, region, or element, it can be directly or indirectly on the other layer, region, or element. That is, for example, intervening layers, regions, or elements may be present.

Sizes of elements in the drawings may be exaggerated or reduced for convenience of explanation. As an example, the size and thickness of each element shown in the drawings are arbitrarily represented for convenience of description, and thus, the disclosure is not necessarily limited thereto.

In the case where a certain embodiment may be implemented differently, a specific process order may be performed in the order different from the described order. As an example, two processes successively described may be simultaneously performed substantially and performed in the opposite order.

In the present specification, "A and/or B" means A or B, or A and B. In the present specification, "at least one of A and B" means A or B, or A and B.

It will be understood that when a layer, region, or element is referred to as being "connected" to another layer, region, or element, it may be "directly connected" to the other layer, region, or element or may be "indirectly connected" to the other layer, region, or element with another layer, region, or element located therebetween. For example, it will be understood that when a layer, region, or element is referred to as being "electrically connected" to another layer, region, or element, it may be "directly electrically connected" to the other layer, region, or element or may be "indirectly electrically connected" to the other layer, region, or element with another layer, region, or element interposed therebetween.

The x-axis, the y-axis and the z-axis are not limited to three axes of the rectangular coordinate system, and may be interpreted in a broader sense. For example, the x-axis, the y-axis, and the z-axis may be perpendicular to one another, or may represent different orientations that are not perpendicular to one another.

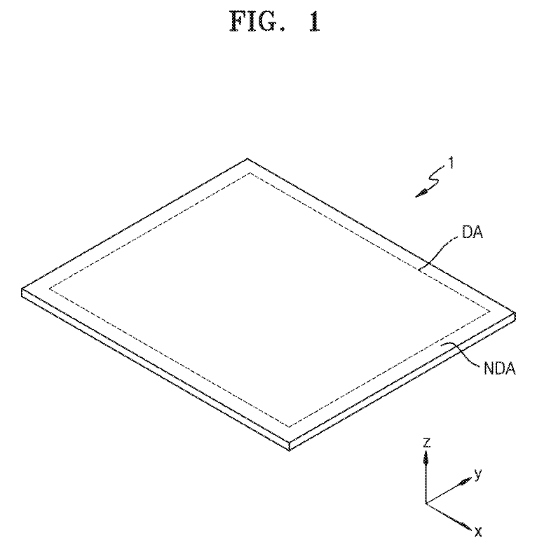

Referring to FIG. 1, a display device 1 may include a display area DA and a non-display area NDA. The display area DA may include a plurality of pixels. The display device 1 may be configured to display images by using light emitted from the plurality of pixels. The non-display area NDA may be disposed outside the display area DA. The non-display area NDA is a region in which the pixels are not disposed and may surround the display area DA entirely.

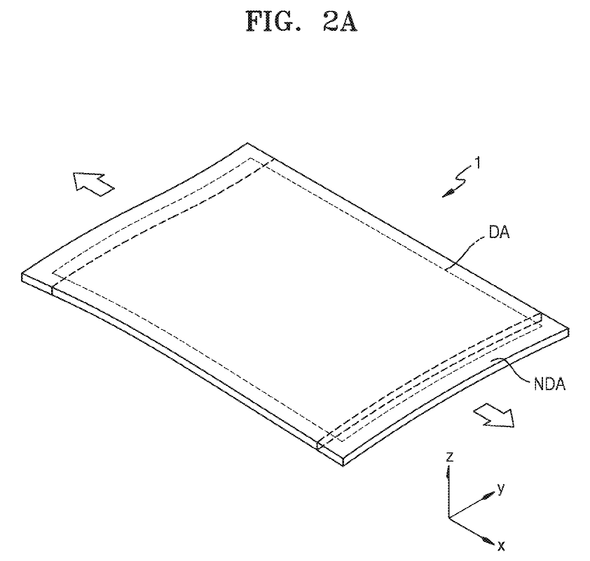

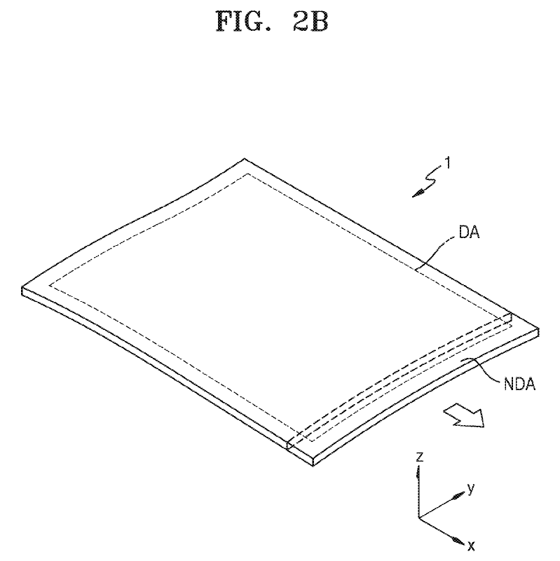

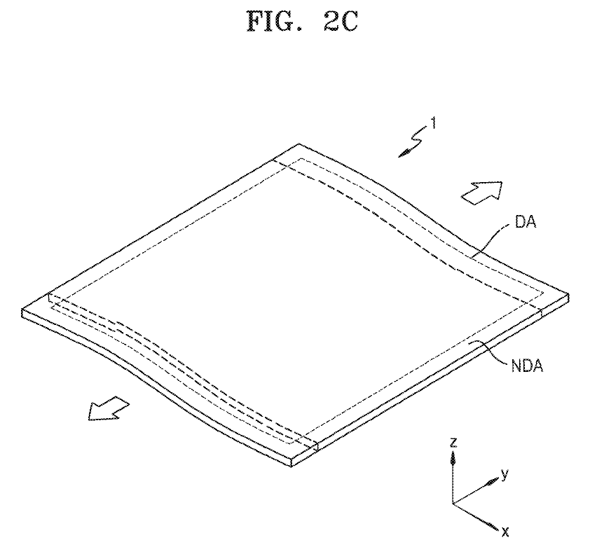

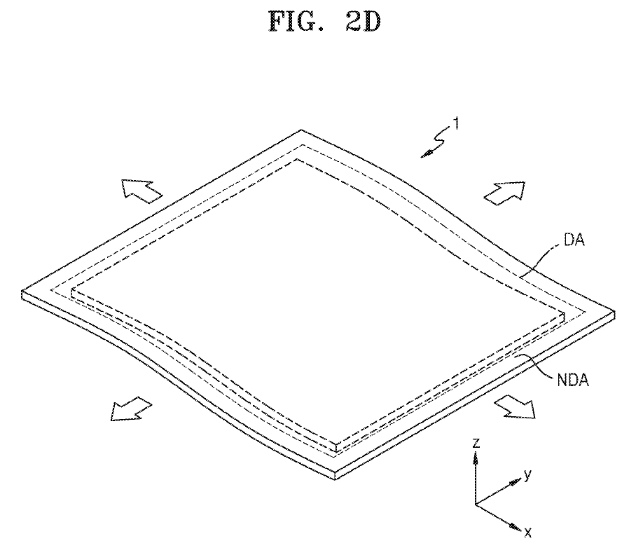

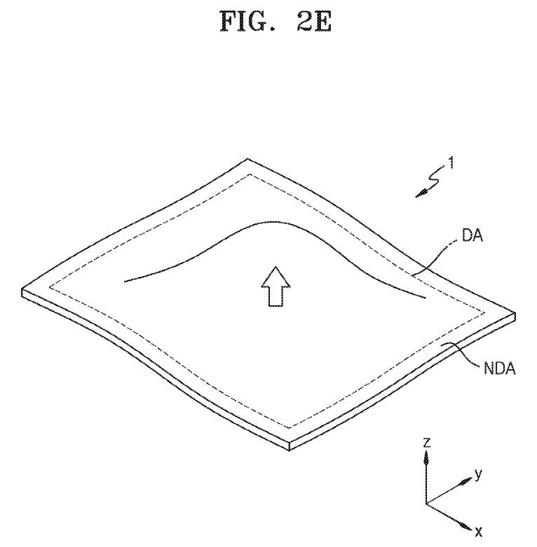

The display device 1 may be stretched or shrunk in various directions. The display device 1 may be stretched in a first direction (e.g., an x direction and/or an -x direction) by an external force exerted by an external object or a user. In an embodiment, as shown in FIGS. 2A and 2B, the display area DA and/or the non-display area NDA of the display device 1 may be stretched in the first direction (e.g., the x direction and/or the -x direction). As an example, as shown in FIG. 2A, the display area DA and/or the non-display area NDA may be stretched in the x direction and -x direction, or as shown in FIG. 2B, be stretched in the x direction with one side of the display device 1 fixed.

The display device 1 may be stretched in a second direction (e.g., a y direction and/or a -y direction) by an external force exerted by an external object or a user. In an embodiment, as shown in FIG. 2C, the display area DA and/or the non-display area NDA of the display device 1 may be stretched in the y direction and the -y direction. In another embodiment, the display device 1 may be stretched in the y direction or the -y direction with one side of the display device 1 fixed.

The display device 1 may be stretched in a plurality of directions, for example, the first direction (e.g., the x direction and/or the -x direction) and the second direction (e.g., the y direction and/or the -y direction) by an external force exerted by an external object or a portion of a person’s body. As shown in FIG. 2D, the display area DA and/or the non-display area NDA of the display device 1 may be stretched in the ±x directions and the ±y directions.

The display device 1 may be stretched in a third direction (e.g., a z direction and/or a -z direction) by an external force exerted by an external object or a portion of a person's body. In an embodiment, FIG. 2E shows a portion of the display device 1, for example, a partial region of the display area DA protrudes in the z direction. In another embodiment, a portion of the display device 1, for example, a partial region of the display area DA may protrude in the -z direction (or be recessed in the z direction).

Although it is shown in FIGS. 2A-2E that the display device 1 is stretched in the first direction, the second direction, and/or the third direction, the present disclosure is not limited thereto. In another embodiment, the display device 1 may be variously deformed into an irregular shape, such as, by bending or twisting with two or more axes.

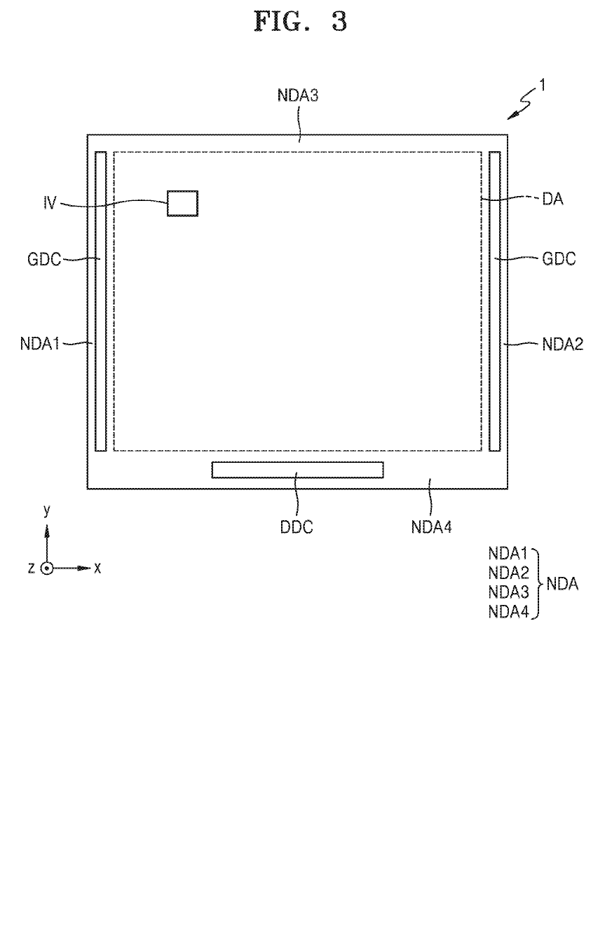

FIG. 3 is a schematic plan view of the display device 1 according to an embodiment. As used herein, the “plan view” is a view in a thickness direction (e.g., a z direction) of the display device 1.

The plurality of pixels may be arranged in the display area DA of the display device 1. Each pixel may include sub-pixels emitting light of different colors from each other. A light-emitting element (e.g., a light-emitting diode) corresponding to each sub-pixel may be disposed in the display area DA. A circuit may be located in the non-display area NDA around the display area DA, wherein the circuit provides electrical signals to light-emitting elements disposed in the display area DA and transistors electrically connected to the light-emitting elements. A gate driving circuit GDC may be disposed in each of a first non-display area NDA1 and a second non-display area NDA2 disposed on two opposite sides with the display area DA therebetween. The gate driving circuit GDC may include drivers for providing electrical signals to a gate electrode of each of the transistors electrically connected to the light-emitting elements. Although it is shown in FIG. 3 that the gate driving circuit GDC is disposed in each of the first non-display area NDA1 and the second non-display area NDA2, the present disclosure is not limited thereto. In another embodiment, the gate driving circuit GDC may be disposed in one of the first non-display area NDA1 and the second non-display area NDA2.

A data driving circuit DDC may be disposed in a third non-display area NDA3 and/or a fourth non-display area NDA4 connecting the first non-display area NDA1 and the second non-display area NDA2 to each other. In an embodiment, it is shown in FIG. 3 that the data driving circuit DDC is disposed in the fourth non-display area NDA4. In another embodiment, the data driving circuit DDC may be disposed in each of the third non-display area NDA3 and the fourth non-display area NDA4.

Although it is shown in FIG. 3 that the data driving circuit DDC is disposed in the fourth non-display area NDA4 of the display device 1, the present disclosure is not limited thereto. In another embodiment, the display device 1 may further include a flexible circuit board (not shown) electrically connected through a terminal section (not shown) disposed in the fourth non-display area NDA4, and the data driving circuit DDC may be disposed on the flexible circuit board.

In another embodiment, an elongation of the non-display area NDA may be equal to or less than an elongation of the display area DA. In an embodiment, an elongation of the non-display area NDA may be different for each region. As an example, the first non-display area NDA1, the second non-display area NDA2, and the third non-display area NDA3 may have substantially the same elongation, but an elongation of the fourth non-display area NDA4 may be less than an elongation of each of the first non-display area NDA1, the second non-display area NDA2, and the third non-display area NDA3. In the present specification, an elongation is a numerical value representing a change ΔL/L in length by which the display device 1 may be stretched without physical damage to the display device 1 when an external force is applied to the display device 1. Here, ΔL is the amount of change in length of the display device 1, and L represents an initial length of the display device 1.

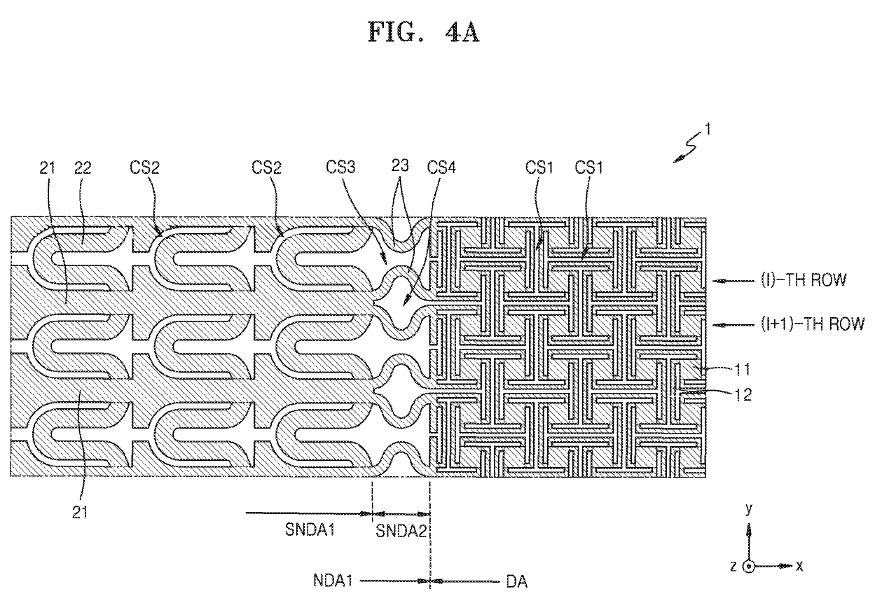

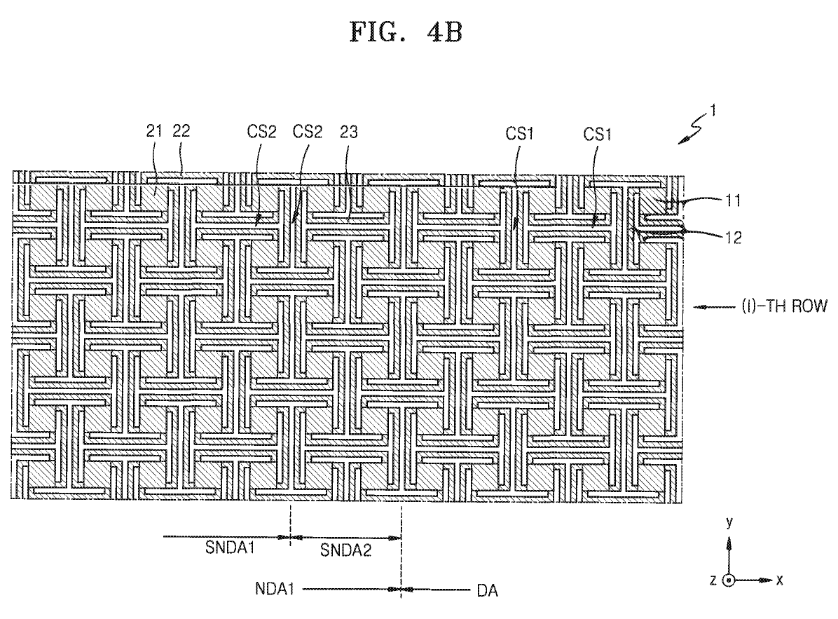

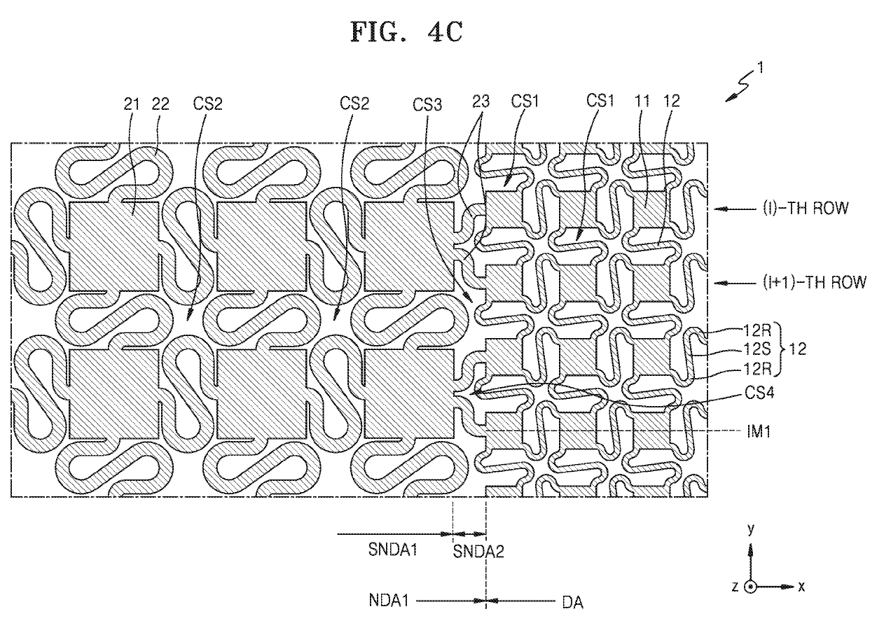

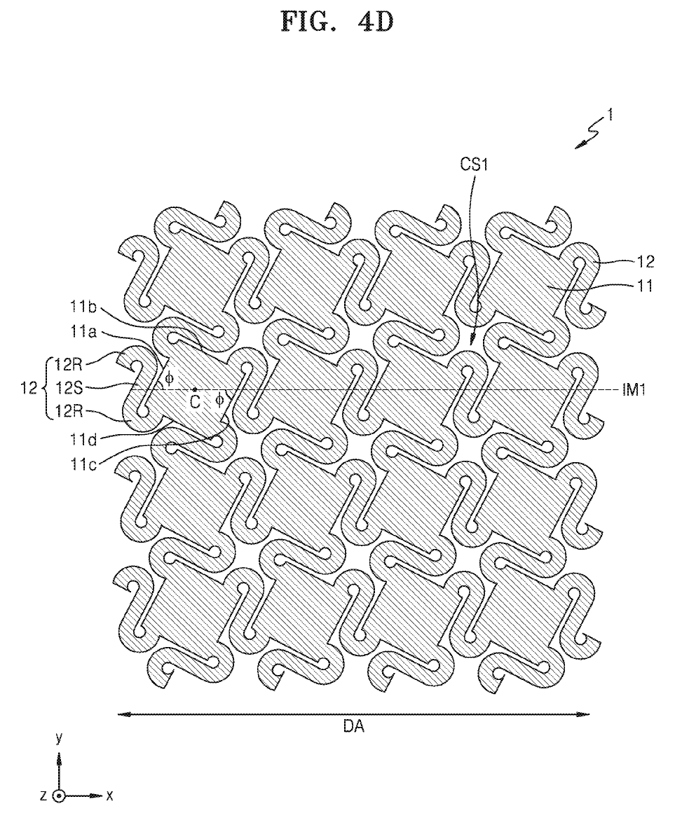

FIG. 4A is an enlarged plan view of a portion of the display device 1, showing a portion IV of FIG. 3 according to an embodiment.

Referring to FIG. 4A, the display device 1 may include first island portions 11 and first bridge portions 12 connecting adjacent first island portions 11, wherein the first island portions 11 are apart from each other in the first direction (e.g., the x direction or the -x direction) and the second direction (e.g., the y direction or the -y direction) in the display area DA.

Each first island portion 11 may be connected to a plurality of first bridge portions 12. As an example, each first island portion 11 may be connected to four first bridge portions 12. Two first bridge portions 12 may be disposed on two opposite sides of the first island portion 11 in the first direction (e.g., the x direction or the -x direction), and the remaining two first bridge portions 12 may be disposed on two opposite sides of the first island portion 11 in the second direction (e.g., the y direction or the -y direction). In an embodiment, four first bridge portions 12 may be connected to four sides of the first island portion 11, respectively. Four first bridge portions 12 may be adjacent to the corners of the first island portion 11, respectively.

The first bridge portions 12 may be apart from each other by a first opening CS1 located between the first bridge portions 12. In an embodiment, the first opening CS1 having an approximate “H” shape and a first opening CS1 having an approximate I shape that is obtained by rotating the H shape by 90° may be alternately and repeatedly arranged in the first direction (e.g., the x direction or the -x direction) and the second direction (e.g., the y direction or the -y direction). Two opposite ends of each first bridge portion 12 are connected to adjacent first island portions 11, respectively, and one side of each first bridge portion 12 may be apart from one side of an adjacent first island portion 11 and/or one side of another first bridge portion 12 by the first opening CS1.

The display device 1 may include second island portions 21 apart from each other, and second bridge portions 22 connecting adjacent second island portions 21 in the non-display area, for example, the first non-display area NDA1 shown in FIG. 4A.

Each second island portion 21 may extend in the first direction (e.g., the x direction or the -x direction). The second island portions 21 may be apart from each other in the second direction (e.g., the y direction or the -y direction) crossing the first direction (e.g., the x direction or the -x direction). Each second island portion 21 may include drivers of the gate driving circuit GDC (FIG. 2) described with reference to FIG. 3.

The second bridge portion 22 may have a serpentine shape. The length of the second bridge portion 22 may be greater than the shortest distance between adjacent second island portions 21 in the second direction (e.g., the y direction or the -y direction). In an embodiment, the second bridge portion 22 may approximately have an omega (Ω) shape that is convex toward the first direction (e.g., the x direction or the -x direction). The second bridge portions 22 may be disposed between adjacent second island portions 21 and be apart from each other.

The second bridge portions 22 between adjacent second island portions 21 may be apart from each other by a second opening CS2. Between adjacent second island portions 21, the second openings CS2 and the second bridge portions 22 may be alternately arranged in the first direction (e.g., the x direction or the -x direction). The second openings CS2 may have the same shape. Two opposite ends of each second bridge portion 22 are connected to adjacent second island portions 21, respectively, and one side of each second bridge portion 22 may be apart from one side of an adjacent second island portion 21 and/or one side of another second bridge portion 22 by the second opening CS2.

One of the second island portions 21 disposed in the first non-display area NDA1 may correspond to first island portions 11 in a plurality of rows arranged in the display area DA. As an example, one of the second island portions 21 disposed in the first non-display area NDA1 may correspond to first island portions 11 arranged in an i-th row in the display area DA, and first island portions 11 arranged in an (i+1)-th row in the display area DA (here, i is a positive number greater than 0). Although it is shown in FIG. 4A that the second island portion 21 corresponds to two rows of the first island portions 11, the present disclosure is not limited thereto. In another embodiment, one of second island portions 21 disposed in the first non-display area NDA1 may correspond to n rows of the first island portions 11 disposed in the display area DA (here, i is a positive number equal to or greater than 3).

The non-display area, for example, the first non-display area NDA1, may include a first sub-non-display area SNDA1 in which the second island portions 21 and the second bridge portions 22 are disposed, and a second sub-non-display area SNDA2 between the first sub-non-display area SNDA1 and the display area DA. Third bridge portions 23 may be disposed in the second sub-non-display area SNDA2, wherein the third bridge portions 23 connect the display area DA to the first sub-non-display area SNDA1. One end of the third bridge portion 23 may be connected to the second island portion 21 and/or the second bridge portion 22, and another end of the third bridge portion 23 may be connected to the first island portion 11 and/or the first bridge portion 12.

The third bridge portion 23 may have a serpentine shape. In an embodiment, the shape of the third bridge portion 23 may be different from the shape of each of the first bridge portion 12 and the second bridge portion 22. In an embodiment, as shown in FIG. 4A, the third bridge portion 23 may approximately have an omega (Ω) shape that is convex toward the second direction (e.g., the y direction or the -y direction). The third bridge portions 23 may have a symmetrical structure in which one of adjacent third bridge portions 23 arranged in the second direction (e.g., the y direction or the -y direction) may be convex in the y direction and the other may be convex in the -y direction. Between the third bridge portions 23, a structure in which a third opening CS3 and a fourth opening CS4 having different shapes from each other are repeated may be provided. The width of the third bridge portion 23 may be different from the width of the first bridge portion 12 and the width of the second bridge portion 22. In an embodiment, the width of the third bridge portion 23 may be greater than the width of the first bridge portion 12 and less than the width of the second bridge portion 22.

It is shown in FIG. 4A that the second island portion 21 and the second bridge portion 22 in the non-display area, for example, the first non-display area NDA1, have shapes different from the shapes of the first island portion 11 and the first bridge portion 12 in the display area DA, respectively. In another embodiment of the present disclosure, the second island portion 21 and the second bridge portion 22 in the non-display area may have the same shape as the shape of the first island portion 11 and the first bridge portion 12 in the display area DA, respectively.

FIG. 4B is an enlarged plan view of a portion of the display device 1, showing a portion IV of FIG. 3 according to an embodiment.

Referring to FIG. 4B, the display device 1 includes the first island portions 11 apart from each other in the display area DA, and the first bridge portions 12 apart from each other by the first opening CS1 and connecting adjacent first island portions 11 to each other. The structure of the display area DA in FIG. 4B may be the same as the structure of the display area DA described above with reference to FIG. 4A.

The display device 1 may include the second island portions 21 and the second bridge portions 22 disposed in the non-display area, for example, the first non-display area NDA1. In an embodiment, the second island portions 21 and the second bridge portions 22 may have the same shapes as the shapes of the first island portions 11 and the first bridge portions 12, respectively.

The second island portions 21 may be apart from each other in the first direction (e.g., the x direction or the -x direction) and the second direction (e.g., the y direction or the -y direction) in the non-display area, for example, the first non-display area NDA1. Each of the second bridge portions 22 may connect adjacent second island portions 21 to each other. The second bridge portions 22 may be apart from each other by the second opening CS2 located between the second bridge portions 22.

The second opening CS2 may have substantially the same shape as the shape of the first opening CS1. As an example, the second opening CS2 having an approximate H shape and the second opening CS2 having an approximate I shape may be alternately and repeatedly arranged in the non-display area, for example, the first non-display area NDA1. Two opposite ends of each second bridge portion 22 are connected to adjacent second island portions 21, respectively, and one side of each second bridge portion 22 may be apart from one side of an adjacent second island portion 21 and/or one side of another second bridge portion 22 by the second opening CS2.

Each second island portion 21 may be connected to four second bridge portions 22. Each second island portion 21 may include drivers of the gate driving circuit GDC (FIG. 2) described with reference to FIG. 3.

The second island portions 21 in one of rows disposed in the first non-display area NDA1 may correspond to first island portions 11 in one of rows arranged in the display area DA. As an example, the second island portions 21 arranged in an i-th row in the first direction (e.g., the x direction or -x direction) in the first non-display area NDA1 may correspond to the first island portions 11 arranged in the same row, for example, the i-th row in the display area DA (here, i is a positive number greater than 0).

The display device 1 may include the third bridge portions 23 disposed in the second sub-non-display area SNDA2 connecting the display area DA to the first sub-non-display area SNDA1. The non-display area, for example, the first non-display area NDA1, may include the first sub-non-display area SNDA1 in which the second island portions 21 and the second bridge portions 22 are disposed, and the second sub-non-display area SNDA2 including the third bridge portions 23 and located between the first sub-non-display area SNDA1 and the display area DA. The third bridge portion 23 may be substantially the same as the first bridge portion 12 and the second bridge portion 22. As an example, the width of the third bridge portion 23 may be the same as the width of the first bridge portion 12 and the width of the second bridge portion 22.

FIG. 4C is an enlarged plan view of a portion of the display device, showing a portion IV of FIG. 3 according to an embodiment.

Referring to FIG. 4C, the display device 1 may include first island portions 11 and first bridge portions 12 connecting adjacent first island portions 11 to each other, wherein the first island portions 11 are apart from each other in the first direction (e.g., the x direction or the -x direction) and the second direction (e.g., the y direction or the -y direction) in the display area DA.

The first bridge portions 12 may be apart from each other by a first opening CS1 located between the first bridge portions 12. The first bridge portion 12 may have a serpentine shape. As an example, as shown in FIG. 4C, the first bridge portion 12 may have a shape of an approximate 'alphabet S' such as including two round portions 12R and a straight portion 12S between the two round portions 12R.

Each first island portion 11 may be connected to a plurality of first bridge portions 12. As an example, each first island portion 11 may be connected to four first bridge portions 12. Two first bridge portions 12 may be disposed on two opposite sides of the first island portion 11 in the first direction (e.g., the x direction or -x direction), and the remaining two first bridge portions 12 may be disposed on two opposite sides of the first island portion 11 in the second direction (e.g., the y direction or -y direction). Four first bridge portions 12 may be connected to four sides of the first island portion 11, respectively. Four first bridge portions 12 may be adjacent to the corners of the first island portion 11, respectively.

In the non-display area, for example, the first non-display area NDA1 shown in FIG. 4C, the display device 1 may include the second island portions 21 apart from each other in the first direction (e.g., the x direction or -x direction) and the second direction (e.g., the y direction or -y direction), and the second bridge portions 22 connecting adjacent second island portions 21 to each other.

The second bridge portions 22 may be apart from each other by a second opening CS2 located between the second bridge portions 22. The second bridge portion 22 may have a serpentine shape. As an example, as shown in FIG. 4C, the second bridge portion 22 may approximately have an 'alphabet S' shape. The size and/or width of the second bridge portion 22 may be different from the size and/or width of the first bridge portion 12. As an example, the size and/or width of the second bridge portion 22 may be greater than the size and/or width of the first bridge portion 12. The curvature radius of a round portion of the second bridge portion 22 may be different from the curvature radius of a round portion of the first bridge portion 12. As an example, the curvature radius of a round portion of the second bridge portion 22 may be greater than the curvature radius of a round portion of the first bridge portion 12.

Each second island portion 21 may be connected to a plurality of second bridge portions 22. Each second island portion 21 may be connected to four second bridge portions 22. Two second bridge portions 22 may be disposed on two opposite sides of the second island portion 21 in the first direction (e.g., the x direction or the -x direction), and the remaining two second bridge portions 22 may be disposed on two opposite sides of the second island portion 21 in the second direction (e.g., the y direction or the -y direction). In an embodiment, four second bridge portions 22 may be connected to four sides of the second island portion 21, respectively. Each second bridge portion 22 may be connected to the central portion of each side of the second island portion 21.

The second island portions 21 in one of rows disposed in the first non-display area NDA1 may correspond to the first island portions 11 in a plurality of rows arranged in the display area DA. As an example, the second island portions 21 in one of rows disposed in the first non-display area NDA1 may correspond to first island portions 11 arranged in an i-th row in the display area DA, and first island portions 11 arranged in an (i+1)-th row in the display area DA (here, i is a positive number greater than 0). In another embodiment, the second island portions 21 in one of rows may correspond to n rows of first island portions 11 (here, n is a positive number equal to or greater than 3).

The non-display area, for example, the first non-display area NDA1, may include the first sub-non-display area SNDA1 in which the second island portions 21 and the second bridge portions 22 are disposed, and the second sub-non-display area SNDA2 between the first sub-non-display area SNDA1 and the display area DA. Third bridge portions 23 may be disposed in the second sub-non-display area SNDA2, wherein the third bridge portions 23 connect the display area DA to the first sub-non-display area SNDA1. One end of the third bridge portion 23 may be connected to the second island portion 21, and the another end of the third bridge portion 23 may be connected to the first island portion 11. As an example, one end of the third bridge portion 23 may be connected to the central portion of one side of the second island portion 21, and another end of the third bridge portion 23 may be connected to the central portion of one side of the first island portion 11.

The third bridge portion 23 may have a serpentine shape. In an embodiment, the shape of the third bridge portion 23 may be different from the shape of each of the first bridge portion 12 and the second bridge portion 22. The width of the third bridge portion 23 may be different from the width of the first bridge portion 12 and the width of the second bridge portion 22. The width of the third bridge portion 23 may be greater than the width of the first bridge portion 12 and less than the width of the second bridge portion 22. Between the third bridge portions 23 in the second direction (e.g., the y direction or the -y direction), the third opening CS3 and the fourth opening CS4 having different shapes from each other may be alternately disposed.

FIG. 4D is an enlarged plan view of a portion of a display device 1, showing the display area DA of FIG. 3 according to an embodiment.

Referring to FIG. 4D, the display device 1 may include first island portions 11 and first bridge portions 12 connecting adjacent first island portions 11 to each other, wherein the first island portions 11 are apart from each other in the first direction (e.g., the x direction or the -x direction) and the second direction (e.g., the y direction or the -y direction) in the display area DA. The first bridge portions 12 may be apart from each other by a first opening CS1 located between the first bridge portions 12.

In an embodiment, at least one of sides of the first island portion 11 may be oblique with respect to an imaginary line connecting centers C of the first island portions 11 in the first direction (e.g., the x direction or the -x direction) and/or the second direction (e.g., the y direction or the -y direction). In this regard, it is shown in FIG. 4D that the first island portion 11 includes first to fourth sides 11a, 11b, 11c, and 11d, and the first to fourth sides 11a, 11b, 11c, and 11d extend in a direction oblique with respect to a first imaginary line IM1 connecting the centers C of the first island portions 11 to each other. Although it is shown in FIG. 4D that the first imaginary line IM1 extends in the first direction (e.g., the x direction or the -x direction), the first imaginary line IM1 may extend in the second direction (e.g., the y direction or the -y direction).

In an embodiment, the first side 11a and the third side 11c parallel to each other may cross the first imaginary line IM1. A small angle T (hereinafter, referred to as an inferior angle) among angles formed by the first side 11a and the first imaginary line IM1 may be greater than 0° and less than 90°. The inferior angle T between the third side 11c and the first imaginary line IM1 may be greater than 0° and less than 90°.

The first island portion 11 may be connected to a plurality of first bridge portions 12. As an example, the first island portion 11 may be connected to four first bridge portions 12. Two first bridge portions 12 may be disposed on two opposite sides of the first island portion 11 in the first direction (e.g., the x direction or -x direction), and the remaining two first bridge portions 12 may be disposed on two opposite sides of the first island portion 11 in the second direction (e.g., the y direction or -y direction).

The first bridge portion 12 may have a serpentine shape. As an example, as shown in FIG. 4D, the first bridge portion 12 may have a shape of an approximate 'alphabet S' such as including two round portions 12R and a straight portion 12S between the two round portions 12R.

In an embodiment, as shown in FIG. 4D, the straight portion 12S may be substantially parallel to a side of an adjacent first island portion 11. As an example, the straight portion 12S of each of the first bridge portions 12 located on two opposite sides of the first island portion 11 in the first direction (e.g., the x direction or the -x direction) may be substantially parallel to a side (e.g., the first side 11a and the third side 11c) of the first island portion 11. The straight portion 12S of each of the first bridge portions 12 located on two opposite sides of the first island portion 11 in the second direction (e.g., the y direction or the -y direction) may be substantially parallel to a side (e.g., the second side 11b and the fourth side 11d) of the first island portion 11.

Each of the first island portions 11 shown in FIG. 4D may be understood as each of the first island portions 11 shown in FIG. 4C being rotated by a first angle (e.g., an acute angle) with respect to the center C. Accordingly, at least one of sides of the first island portion 11 may be oblique with respect to an imaginary line connecting the centers C of the first island portions 11 in the first direction (e.g., the x direction or the -x direction) and/or the second direction (e.g., the y direction or the -y direction). Depending on the arrangement of the first island portions 11 and/or the structure of the first bridge portion 12, the area of the first opening CS1 shown in FIG. 4D may be relatively less than the area of the first opening CS1 shown in FIG. 4C, and accordingly, the display device 1 according to the embodiment shown in FIG. 4D may provide relatively high-resolution images.

Although it is shown in FIG. 4D that the straight portion 12S of the first bridge portion 12 is substantially parallel to a side of the first island portion 11 adjacent to the straight portion 12S, the present disclosure is not limited thereto. In another embodiment, the straight portion 12S of the first bridge portion 12 may be oblique to a side of a first island portion 11 adjacent to the straight portion 12S as shown in FIG. 4C.

In an embodiment, the structure of the first non-display area NDA1 (FIG. 3) of the display device 1 not disclosed in FIG. 4D may be the same as the structure of the display area DA disclosed in FIG. 4D. In an embodiment, the structure of the first non-display area NDA1 (FIG. 3) of the display device 1 not disclosed in FIG. 4D may be substantially the same as the structure of the display area DA disclosed in FIG. 4D, and the area of the second island portion disposed in the first non-display area NDA1 (FIG. 3) may be greater than the area of the first island portion 11. In this case, one second island portion may correspond to the plurality of first island portions 11 arranged in adjacent rows as described with reference to FIG. 4C. In an embodiment, the structure of the first non-display area NDA1 (FIG. 3) of the display device 1 not disclosed in FIG. 4D may be substantially the same as the structure of the first non-display area NDA1 shown in one of FIGS. 4A to 4C. As described above, the structure of the first non-display area NDA1 (FIG. 3) may be variously selected in the range disclosed in the present specification.

FIG. 4E is an enlarged plan view of a portion of the display device 1, showing a portion IV of FIG. 3 according to an embodiment.

Referring to FIG. 4E, the display device 1 includes the first island portions 11 apart from each other in the display area DA, and the first bridge portions 12 apart from each other by the first opening CS1 and connecting adjacent first island portions 11 to each other.

The first opening CS1 may have a bar shape. The first opening CS1 may include a first sub-opening CS1A extending in the first direction (e.g., the x direction or the -x direction) and a second sub-opening CS1B extending in the second direction (e.g., the y direction or the -y direction). Each of the first sub-opening CS1A and the second sub-opening CS1B may have a bar shape. The first sub-opening CS1A and the second sub-opening CS1B may have substantially the same width and same length. The length of each of the first sub-opening CS1A and the second sub-opening CS1B represents a value measured in the extension direction, and the width thereof represents a value measured in a direction perpendicular to the length direction (e.g., the extension direction).

The display device 1 may include the second island portions 21 and the second bridge portions 22 disposed in the non-display area, for example, the first sub-non-display area SNDA1. The second island portions 21 may be apart from each other in the first direction (e.g., the x direction or the -x direction) and the second direction (e.g., the y direction or the -y direction) in a first sub-non-display area SNDA1. Each of the second bridge portions 22 may connect adjacent second island portions 21 to each other. The second bridge portions 22 may be apart from each other by a second opening CS2 located between the second bridge portions 22.

The second opening CS2 may have a bar shape. The second opening CS2 may include a first sub-opening CS2A extending in the first direction (e.g., the x direction or the -x direction) and a second sub-opening CS2B extending in the second direction (e.g., the y direction or the -y direction). Each of the first sub-opening CS2A and the second sub-opening CS2B may have a bar shape. The first sub-opening CS2A and the second sub-opening CS2B may have substantially the same width and same length. Each second island portion 21 may be connected to four second bridge portions 22. Each second island portion 21 may include drivers of the gate driving circuit GDC (FIG. 2) described with reference to FIG. 3. Some of the drivers of the gate driving circuit GDC (FIG. 2) may be disposed also in the second sub-non-display area SNDA2. As an example, some of third island portions 31 may include some of the drivers.

One of the second island portions 21 disposed in the first non-display area NDA1 may correspond to first island portions 11 in a plurality of rows arranged in the display area DA. As an example, one of the second island portions 21 disposed in the first non-display area NDA1 may correspond to first island portions 11 arranged in an i-th row in the display area DA, and first island portions 11 arranged in an (i+1)-th row in the display area DA (here, i is a positive integer greater than 0). Although it is shown in FIG. 4E that the second island portion 21 corresponds to two rows of the first island portions 11, the present disclosure is not limited thereto. In another embodiment, one of second island portions 21 disposed in the first non-display area NDA1 may correspond to n rows of the first island portions 11 disposed in the display area DA (here, i is a positive number equal to or greater than 3).

The display device 1 may include the third island portions 31 and third bridge portions 32 disposed in the second sub-non-display area SNDA2 connecting the display area DA to the first sub-non-display area SNDA1. Adjacent third island portions 31 may be apart from each other by the third opening CS3 and connected by the bridge portions 32.

The third opening CS3 may have a bar shape. The third opening CS3 may include a first sub-opening CS3A extending in the first direction (e.g., the x direction or the -x direction) and a second sub-opening CS3B extending in the second direction (e.g., the y direction or the -y direction). Each of the first sub-opening CS3A and the second sub-opening CS3B may have a bar shape. The first sub-opening CS3A and the second sub-opening CS3B may have different widths and/or different lengths from each other.

In an embodiment, the length of the first sub-opening CS3A of the third opening CS3 in the first direction (e.g., the x direction or the -x direction) may be equal to or greater than the length of the second sub-opening CS3B of the third opening CS3 in the second direction (e.g., the y direction or the -y direction). The width of the first sub-opening CS3A of the third opening CS3 in the second direction (e.g., the y direction or the -y direction) may be less than the width of the second sub-opening CS3B of the third opening CS3 in the first direction (e.g., the x direction or the -x direction).

In an embodiment, the length of the first sub-opening CS3A of the third opening CS3 in the first direction (e.g., the x direction or the -x direction) may be equal to the length of the first sub-opening CS2A of the second opening CS2 in the first direction (e.g., the x direction or the -x direction) and greater than the length of the first sub-opening CS1A of the first opening CS1 in the first direction (e.g., the x direction or the -x direction). The width of the first sub-opening CS3A of the third opening CS3 in the second direction (e.g., the y direction or the -y direction) may be less than the width of the first sub-opening CS2A of the second opening CS2 in the second direction (e.g., the y direction or the -y direction) and equal to the width of the first sub-opening CS1A of the first opening CS1 in the second direction (e.g., the y direction or the -y direction).

In an embodiment, the length of the second sub-opening CS3B of the third opening CS3 in the second direction (e.g., the y direction or the -y direction) may be equal to the length of the second sub-opening CS2B of the second opening CS2 in the second direction (e.g., the y direction or the -y direction) and greater than the length of the second sub-opening CS1B of the first opening CS1 in the second direction (e.g., the y direction or the -y direction). The width of the second sub-opening CS3B of the third opening CS3 in the first direction (e.g., the x direction or the -x direction) may be equal to the length of the second sub-opening CS2B of the second opening CS2 in the first direction (e.g., the x direction or the -x direction) and greater than the width of the second sub-opening CS1B of the first opening CS1 in the first direction (e.g., the x direction or the -x direction).

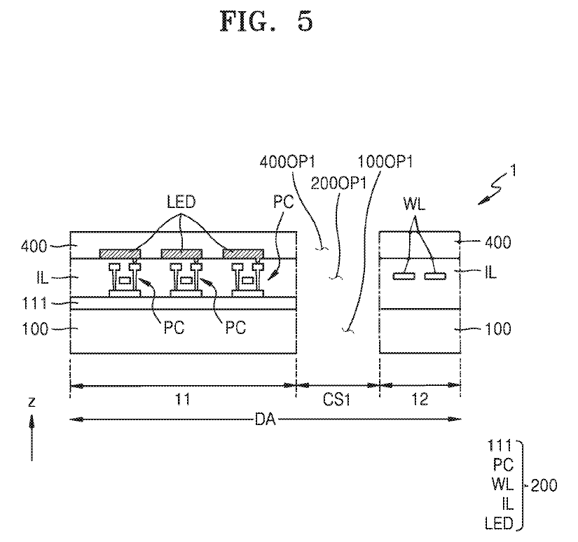

FIG. 5 is a schematic cross-sectional view of the display device 1 according to an embodiment.

Referring to FIG. 5, the first island portion 11 and the first bridge portion 12 disposed in the display area DA may be apart from each other with the first opening CS1 therebetween. The first island portion 11 may include light-emitting diodes LED and a circuit electrically connected thereto and driving the light-emitting diode LED, for example, a pixel driving circuit PC, and the first island portions 11 may include a wiring WL electrically connected to the pixel driving circuits PC disposed in each of adjacent first island portions 11.

In the first island portion 11, a buffer layer 111 including an inorganic insulating material may be disposed on a substrate 100, and the pixel driving circuit PC may be disposed on the buffer layer 111. An insulating layer IL including an inorganic insulating material and/or an organic insulating material may be disposed between the pixel driving circuit PC and the light-emitting diode LED. The light-emitting diode LED may be disposed on the insulating layer IL and electrically connected to the pixel driving circuit PC corresponding thereto. The light-emitting diodes LED may emit light of different colors or light of the same color. In an embodiment, the light-emitting diodes LED may be configured to emit red, green, or blue light. In an embodiment, the light-emitting diodes LED may emit white light. In another embodiment, the light-emitting diodes LED may emit red, green, blue, and white light.

In an embodiment, although it is shown in FIG. 5 that three pixel driving circuits PC are disposed in each first island portion 11, and three light-emitting diodes LED are connected to the pixel driving circuits PC, respectively, the present disclosure is not limited thereto. In another embodiment, the number of pixel driving circuits PC and the number of light-emitting diodes LED disposed in the first island portion 11 may be one, two, or four or more.

An encapsulation layer 400 may be disposed on the light-emitting diode LED and may protect the light-emitting diode LED from an external force and/or moisture transmission. The encapsulation layer 400 may include an inorganic encapsulation layer and/or an organic encapsulation layer. In an embodiment, the encapsulation layer 400 may include a structure in which an inorganic encapsulation layer including an inorganic insulating material, an organic encapsulation layer including an organic insulating material, and an inorganic encapsulation layer including an inorganic insulating material are stacked. In another embodiment, the encapsulation layer 400 may include an organic material such as resin. In an embodiment, the encapsulation layer 400 may include urethane epoxy acrylate. The encapsulation layer 400 may include a photosensitive material, for example, a material such as photoresist.

In the first bridge portion 12, the insulating layer IL including an organic insulating material may be disposed on the substrate 100. When the display device 1 stretches, the first bridge portion 12, which is relatively subject to a large amount of deformation, may not have a layer including an inorganic insulating material that is prone to cracking, unlike the first island portion 11.

In an embodiment, the substrate 100 corresponding to the first bridge portion 12 may have the same stack structure as a stack structure of the substrate 100 corresponding to the first island portion 11. In an embodiment, the substrate 100 corresponding to the first bridge portion 12 and the substrate 100 corresponding to the first island portion 11 may be polymer resin layers simultaneously formed during the same process. In another embodiment, the substrate 100 corresponding to the first bridge portion 12 may have a different stack structure from a stack structure of the substrate 100 corresponding to the first island portion 11. In an embodiment, the substrate 100 corresponding to the first island portion 11 may have a multi-layered structure including a base layer that includes a polymer resin and a barrier layer that includes an inorganic insulating material, and the substrate 100 corresponding to the first bridge portion 12 may have a structure of a polymer resin layer in which a layer including an inorganic insulating material is absent.

As described above, the wirings WL of the first bridge portion 12 may be signal lines (e.g., a gate line, a data line, and the like) for providing electrical signals, or voltage lines (e.g., a driving voltage line, an initialization voltage line, and the like) for providing voltages to transistors included in the pixel driving circuit PC of the first island portion 11. The encapsulation layer 400 may be disposed also on the first bridge portion 12. In another embodiment, the encapsulation layer 400 may not be present in the first bridge portion 12.

Referring to FIGS. 4A to 4E, and 5, the substrate 100 corresponding to the first island portion 11 may be connected to the substrate 100 corresponding to the first bridge portion 12. In other words, the plan views shown in FIGS. 4A-4E may be substantially the same as the plan view of the substrate 100 in FIG. 5. In other words, the substrate 100 may include a region corresponding to the first island portion 11, a region corresponding to the first bridge portion 12, and an opening 100OP1 having the same shape as a shape of the first opening CS1.

Similarly, the encapsulation layer 400 corresponding to the first island portion 11 and the encapsulation layer 400 corresponding to the first bridge portion 12 may be connected to each other. As an example, the plan views shown in FIGS. 4A-4E may be substantially the same as the plan view of the encapsulation layer 400. In other words, the encapsulation layer 400 may include a region corresponding to the first island portion 11, a region corresponding to the first bridge portion 12, and an opening 400OP1 having the same shape as a shape of the first opening CS1.

A circuit-light-emitting element layer 200 between the substrate 100 and the encapsulation layer 400 may include the buffer layer 111, the pixel driving circuit PC, the wiring WL, the insulating layer IL, and the light-emitting diode LED. Similar to the substrate 100, the plan views shown in FIGS. 4A-4E may be substantially the same as the plan view of the circuit-light-emitting element layer 200. In other words, the circuit-light-emitting element layer 200 may include an opening 200OP1 having the same shape as the shape of the first opening CS1.

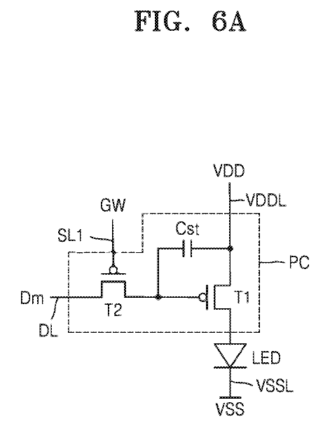

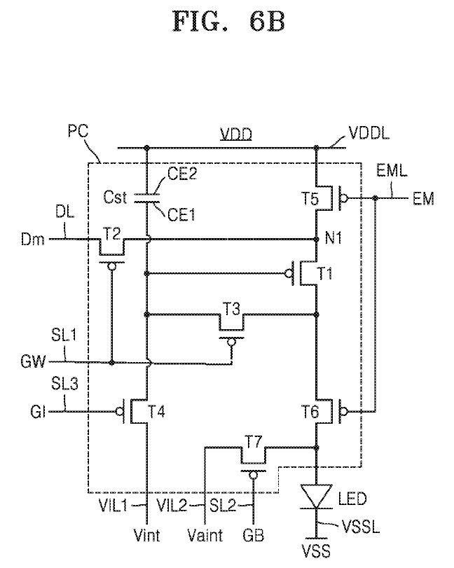

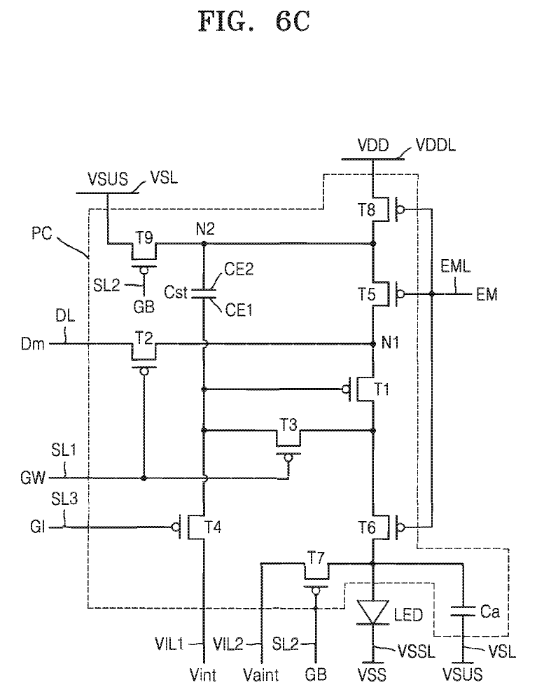

FIGS. 6A-6C are equivalent circuit diagrams of a sub-pixel of the display device 1 according to an embodiment.

Referring to FIG. 6A, the light-emitting diode LED corresponding to a sub-pixel may be electrically connected to the pixel driving circuit PC, and the pixel driving circuit PC may include a first transistor T1, a second transistor T2, and a storage capacitor Cst. The pixel driving circuit PC may be electrically connected to a signal line and a voltage line. The signal line may include a gate line such as a first scan line SL1, and a data line DL, and the voltage line may include a first voltage line VDDL.

The second transistor T2 may be electrically connected to the first scan line SL1 and the data line DL. The first scan line SL1 may provide a first scan signal GW to a gate electrode of the second transistor T2. The second transistor T2 may transfer a data signal Dm to the first transistor T1 according to a first scan signal GW input from the first scan line GL1, wherein the data signal Dm is input from the data line DL.

The storage capacitor Cst may be electrically connected to the second transistor T2 and the first voltage line VDDL and may store a voltage corresponding to a difference between a voltage transferred from the second transistor T2 and a first power voltage VDD supplied by the first voltage line VDDL.

The first transistor T1 is a driving transistor and may control a driving current flowing through the light-emitting diode LED. The first transistor T1 may be connected to the first voltage line VDDL and the storage capacitor Cst. The first transistor T1 may control the driving current flowing from the first voltage line VDDL to the light-emitting diode LED in response to a voltage value stored in the storage capacitor Cst. The light-emitting diode LED may emit light having a preset brightness corresponding to the driving current. A first electrode of the light-emitting diode LED may be electrically connected to the first transistor T1, and a second electrode may be electrically connected to a second voltage line VSSL supplying a second power voltage VSS.

Although it is shown in FIG. 6A that the pixel driving circuit PC includes two transistors and one storage capacitor, the pixel driving circuit PC may include three or more transistors in another embodiment.

Referring to FIG. 6B, the pixel driving circuit PC may include the first transistor T1, the second transistor T2, a third transistor T3, a fourth transistor T4, a fifth transistor T5, a sixth transistor T6, a seventh transistor T7, and the storage capacitor Cst.

The pixel driving circuit PC is electrically connected to signal lines and voltage lines. The signal lines may include a gate line such as the first scan line SL1, a second scan line SL2, a third scan line SL3, and an emission control line EML, and the data line DL. The voltage lines may include first and second initialization voltage lines VIL1 and VIL2, and the first voltage line VDDL.

The first voltage line VDDL may transfer the first power voltage VDD to the first transistor T1. The first initialization voltage line VIL1 may transfer a first initialization voltage Vint to the pixel driving circuit PC, wherein the first initialization voltage Vint initializes the first transistor T1. The second initialization voltage line VIL2 may transfer a second initialization voltage Vaint to the pixel driving circuit PC, wherein the second initialization voltage Vaint initializes the first electrode of the light-emitting diode LED.

The first transistor T1 may be connected to the first voltage line VDDL through the fifth transistor T5 and electrically connected to the light-emitting diode LED through the sixth transistor T6. The first transistor T1 serves as a driving transistor, and receives a data signal Dm and supplies the driving current to the light-emitting diode LED according to a switching operation of the second transistor T2.

The second transistor T2 is a data-write transistor and is electrically connected to the first scan line SL1 and the data line DL. The second transistor T2 is electrically connected to the first voltage line VDDL through the fifth transistor T5. The second transistor T2 is turned on according to a first scan signal GW transferred through the first scan line SL1, and performs a switching operation of transferring a data signal Dm to a first node N1, the data signal Dm being transferred through the data line DL.

The third transistor T3 is electrically connected to the first scan line SL1 and electrically connected to the light-emitting diode LED through the sixth transistor T6. The third transistor T3 may be turned on according to a first scan signal GW to diode-connect the first transistor T1, wherein the first scan signal GW is transferred through the first scan line SL1.

The fourth transistor T4 serves as a first initialization transistor and is electrically connected to the third scan line SL3 and the first initialization voltage line VIL1. The fourth transistor T4 may be turned on according to a third scan signal GI to initialize a voltage of the gate electrode of the first transistor T1 by transferring the first initialization voltage Vint to the gate electrode of the first transistor T1, wherein the first initialization voltage Vint is from the first initialization voltage line VIL1, and the third scan signal GI is transferred through the third scan line SL3. The third scan signal GI may correspond to a first scan signal of another pixel driving circuit disposed in a previous row of the relevant pixel driving circuit PC.

The fifth transistor T5 may be an operation control transistor, and the sixth transistor T6 may be an emission control transistor. The fifth transistor T5 and the sixth transistor T6 may be electrically connected to the emission control line EML, simultaneously turned on according to an emission control signal EM transferred through the emission control line EML, and may form a current path such that the driving current flows in a direction from the first voltage line VDDL to the light-emitting diode LED.

The seventh transistor T7 is a second initialization transistor and may be electrically connected to the second scan line SL2, the second initialization voltage line VIL2, and the sixth transistor T6. The seventh transistor T7 is turned on according to a second scan signal GB transferred through the second scan line SL2, and is configured to transfer the second initialization voltage Vaint from the second initialization voltage line VIL2 to the first electrode of the light-emitting diode LED, thereby initializing the first electrode of the light-emitting diode LED.

The storage capacitor Cst includes a first electrode CE1 and a second electrode CE2. The first electrode CE1 is electrically connected to the gate electrode of the first transistor T1, and the second electrode CE2 is electrically connected to the first voltage line VDDL. The storage capacitor Cst may maintain a voltage applied to the gate electrode of the first transistor T1 by storing and maintaining a voltage corresponding to a difference between voltages of two opposite ends of the gate electrode of the first transistor T1 and the first voltage line VDDL.

Referring to FIG. 6C, the pixel driving circuit PC may include the first transistor T1, the second transistor T2, the third transistor T3, the fourth transistor T4, the fifth transistor T5, the sixth transistor T6, the seventh transistor T7, an eighth transistor T8, a ninth transistor T9, the storage capacitor Cst, and an auxiliary capacitor Ca.

The pixel driving circuit PC is electrically connected to signal lines and voltage lines. The signal lines may include a gate line such as the first scan line SL1, the second scan line SL2, the third scan line SL3, and the emission control line EML, and the data line DL. The voltage lines may include the first and second initialization voltage lines VIL1 and VIL2, a sustain voltage line VSL, and the first voltage line VDDL.

The first voltage line VDDL may transfer the first power voltage VDD to the first transistor T1. The first initialization voltage line VIL1 may transfer the first initialization voltage Vint to the pixel driving circuit PC, wherein the first initialization voltage Vint initializes the first transistor T1. The second initialization voltage line VIL2 may transfer a second initialization voltage Vaint to the pixel driving circuit PC, wherein the second initialization voltage Vaint initializes the first electrode of the light-emitting diode LED. The sustain voltage line VSL may provide a sustain voltage VSUS to a second node N2, for example, the second electrode CE2 of the storage capacitor Cst during an initialization section and a data-write section.

The first transistor T1 may be electrically connected to the first voltage line VDDL through the fifth transistor T5 and the eighth transistor T8 and electrically connected to the light-emitting diode LED through the sixth transistor T6. The first transistor T1 serves as a driving transistor, and may receive a data signal Dm and supply the driving current to the light-emitting diode LED according to a switching operation of the second transistor T2.

The second transistor T2 is electrically connected to the first scan line SL1 and the data line DL and electrically connected to the first voltage line VDDL through the fifth transistor T5 and the eighth transistor T8. The second transistor T2 may be turned on according to a first scan signal GW transferred through the first scan line SL1 and may perform a switching operation of transferring a data signal Dm to the first node N1, wherein the data signal Dm is transferred through the data line DL.

The third transistor T3 is electrically connected to the first scan line SL1 and electrically connected to the light-emitting diode LED through the sixth transistor T6. The third transistor T3 may be turned on according to a first scan signal GW to compensate for a threshold voltage of the first transistor T1 by diode-connecting the first transistor T1, wherein the first scan signal GW is transferred through the first scan line SL1.

The fourth transistor T4 is electrically connected to the third scan line SL3 and the first initialization voltage line VIL1, turned on according to a third scan signal GI transferred through the third scan line SL3, and initializes a voltage of the gate electrode of the first transistor T1 by transferring the first initialization voltage Vint from the first initialization voltage line VIL1 to the gate electrode of the first transistor T1. The third scan signal GI may correspond to a first scan signal of another pixel driving circuit disposed in a previous row of the relevant pixel driving circuit PC.

The fifth transistor T5, the sixth transistor T6, and the eighth transistor T8 may be electrically connected to the emission control line EML, simultaneously turned on according to an emission control signal EM transferred through the emission control line EML, and may form a current path such that the driving current flows in a direction from the first voltage line VDDL to the light-emitting diode LED.

The seventh transistor T7 is a second initialization transistor and may be electrically connected to the second scan line SL2, the second initialization voltage line VIL2, and the sixth transistor T6. The seventh transistor T7 is turned on according to a second scan signal GB transferred through the second scan line SL2, and is configured to transfer the second initialization voltage Vaint from the second initialization voltage line VIL2 to the first electrode of the light-emitting diode LED, thereby initializing the first electrode of the light-emitting diode LED.

The ninth transistor T9 may be electrically connected to the second scan line SL2, the second electrode CE2 of the storage capacitor Cst, and the sustain voltage line VSL. The ninth transistor T9 is turned on according to a second scan signal GB transferred through the second scan line SL2 and may transfer the sustain voltage VSUS to the second node N2, for example, the second electrode CE2 of the storage capacitor Cst during the initialization section and the data-write section.

Each of the eighth transistor T8 and the ninth transistor T9 may be electrically connected to the second node N2, for example, the second electrode CE2 of the storage capacitor Cst. In an embodiment, during the initialization section and the data-write section, the eighth transistor T8 may be turned off and the ninth transistor T9 may be turned on. During an emission section, the eighth transistor T8 may be turned on and the ninth transistor T9 may be turned off. Because the sustain voltage VSUS is transferred to the second node N2 during the initialization section and the data-write section, uniformity (e.g., long range uniformity (LRU)) in brightness of the display device depending on a voltage drop of the first voltage line VDDL may be improved.

The storage capacitor Cst includes the first electrode CE1 and the second electrode CE2. The first electrode CE1 is electrically connected to the gate electrode of the first transistor T1, and the second electrode CE2 is electrically connected to the eighth transistor T8 and the ninth transistor T9.

The auxiliary capacitor Ca may be electrically connected to the sixth transistor T6, the sustain voltage line VSL, and the first electrode of the light-emitting diode LED. The auxiliary capacitor Ca may prevent a black brightness from rising when the sixth transistor T6 is turned off by storing and maintaining a voltage corresponding to a voltage difference between the first electrode of the light-emitting diode LED and the sustain voltage line VSL while the seventh transistor T7 and the ninth transistor T9 are turned on.

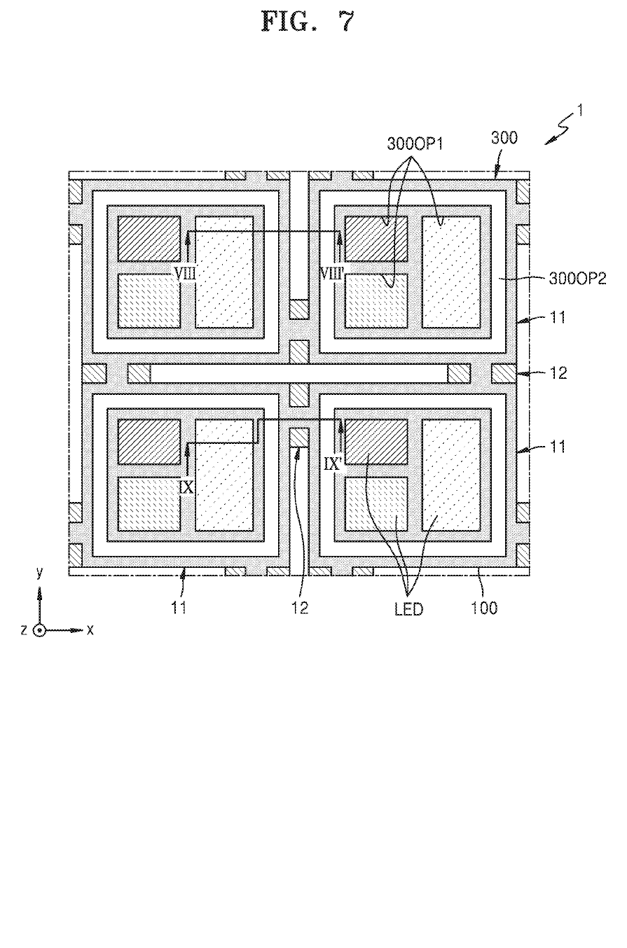

FIG. 7 is a schematic plan view of a portion of the display device 1, for example, a display area DA (FIG. 3) according to an embodiment.

Referring to FIG. 7, the display device 1 may include the first island portions 11 and the first bridge portions 12, and the light-emitting diodes LED may be disposed on the substrate 100 corresponding to the first island portions 11 and the first bridge portions 12. The light-emitting diodes LED disposed in the first island portions 11, respectively, may emit light of different colors (e.g., red, green, and blue). The light-emitting diode LED may be located in the first island portion 11. Although it is shown in FIG. 7 that three light-emitting diodes LED are disposed in the first island portion 11, the present disclosure is not limited thereto. In another embodiment, one or two, or four or more light-emitting diodes LED may be located in the first island portion 11.

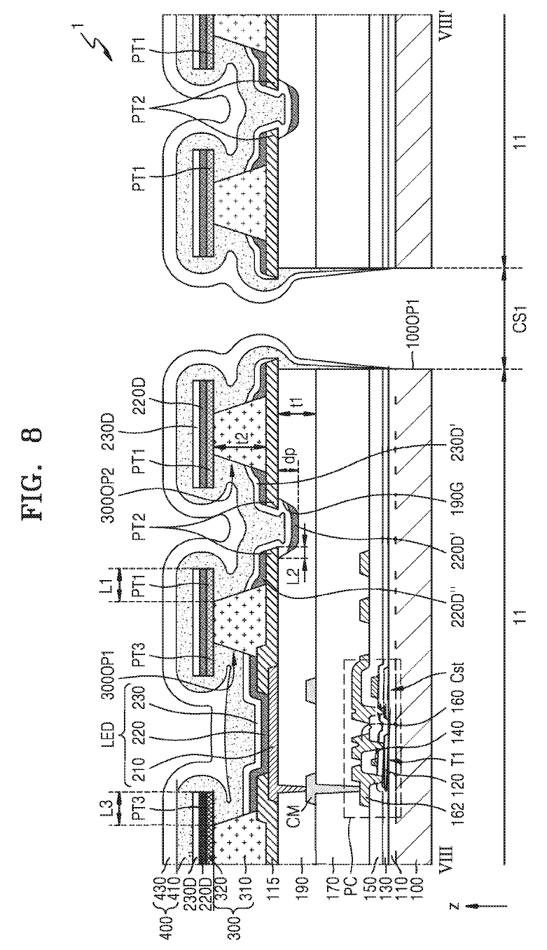

A bank layer 300 may be disposed on the substrate 100 and may include first openings 300OP1 and second openings 300OP2. The first openings 300OP1 are openings corresponding to the light-emitting diodes LED, respectively, and may define the emission areas of the light-emitting diodes LED. In a plan view, (when viewed in a direction perpendicular to the substrate 100) each second opening 300OP2 may surround (e.g., entirely surround) at least one first opening 300OP1 in a plan view. In an embodiment, as shown in FIG. 7, in the case where three light-emitting diodes LED are located in the first island portion 11, in a plan view, each second opening 300OP2 may surround three first openings 300OP1 in a plan view. The second opening 300OP is a construction for separating organic materials included in an intermediate layer of the light-emitting diode LED and may effectively separate the organic materials through an eaves structure of the second opening 300OP and an additional eaves structure disposed between the second opening 300OP2 and the substrate 100. A specific structure related to this is described in a relevant section with reference to FIGS. 8-10.

The bank layer 300 may be electrically connected to an opposite electrode of the light-emitting diode LED and may have the same voltage level as the opposite electrode, for example, the voltage level of the second power voltage VSS. In a plan view, the bank layer 300 may have a net structure including the first openings 300OP1 and the second openings 300OP2. In other words, the structure of the bank layer 300 corresponding to one of the first island portions 11 may be connected to the structure of the bank layer 300 corresponding to another of the first island portions 11.

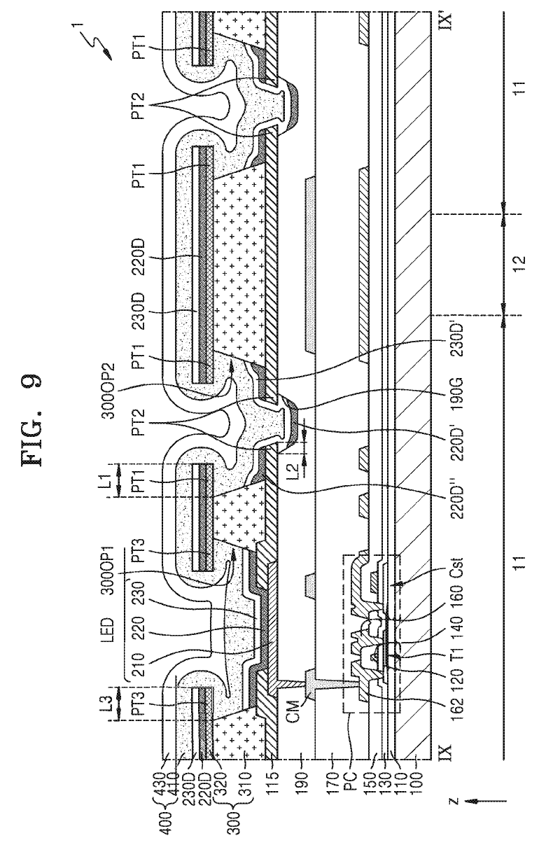

FIGS. 8 and 9 are cross-sectional views of the display device 1 according to an embodiment, FIG. 8 is a cross-sectional view taken along line VIII-VIII' of FIG. 7, and FIG. 9 is a cross-sectional view taken along line IX-IX' of FIG. 7.

Referring to FIGS. 8 and 9, the light-emitting diode LED may be disposed in the first island portion 11, and the light-emitting diode LED may be electrically connected to the pixel driving circuit PC disposed between the substrate 100 and the light-emitting diode LED.

The substrate 100 may include polymer resin such as polyethersulfone, polyarylate, polyetherimide, polyethylene naphthalate, polyethylene terephthalate, polyphenylene sulfide, polyimide, polycarbonate, cellulose triacetate, cellulose acetate propionate, and the like. In an embodiment, the substrate 100 may be a single layer including the polymer resin. In another embodiment, the substrate 100 may have a multi-layered structure including a base layer and a barrier layer, wherein the base layer includes the above polymer resin and the barrier layer includes an inorganic insulating material. The substrate 100 including the polymer resin may be flexible, rollable, or bendable. As described above with reference to FIG. 5, the substrate 100 may include the opening 100OP1 corresponding to the first opening CS1.

The pixel driving circuit PC may be disposed on the substrate 100. The pixel driving circuit PC may include the transistors and the storage capacitor described with reference to FIGS. 6A- 6C. In an embodiment, it is shown in FIGS. 8 and 9 that the pixel driving circuit PC includes the first transistor T1 and the storage capacitor Cst.

The buffer layer 110 may be disposed between the substrate 100 and the first transistor T1. The buffer layer 110 may prevent impurities from penetrating a semiconductor layer of the transistor. The buffer layer 110 may include an inorganic insulating material such as silicon nitride, silicon oxynitride, and silicon oxide, and include a single layer or a multi-layer including the above inorganic insulating materials.

The first transistor T1 may include a first semiconductor layer 120 and a first gate electrode 140, wherein the first semiconductor layer 120 is on the buffer layer 110, and the first gate electrode 140 overlaps a channel region of the first semiconductor layer 120 in a plan view. The first semiconductor layer 120 may include a silicon-based semiconductor material, for example, polycrystalline silicon. Alternatively, the first semiconductor layer 120 may include an oxide-based semiconductor material. The first semiconductor layer 120 may include the channel region, a first region, and a second region, the first region and the second region being on two opposite sides of the channel region. The first region and the second region are regions including impurities of higher concentration than the concentration of the channel region, or regions made conductive. One of the first region and the second region may correspond to a source region, and the other may correspond to a drain region.

A gate insulating layer 130 may be disposed between the first semiconductor layer 120 and the first gate electrode 140. The gate insulating layer 130 may include an inorganic insulating material such as silicon nitride, silicon oxynitride, and silicon oxide, and include a single layer or a multi-layer including the above inorganic insulating materials.

A first interlayer-insulating layer 150 may be disposed on the first gate electrode 140. The first interlayer-insulating layer 150 may include an inorganic insulating material such as silicon nitride, silicon oxynitride, and silicon oxide, and include a single layer or a multi-layer including the above inorganic insulating materials.

A source electrode 160 and a drain electrode 162 may be electrically connected to the source region and the drain region of the first semiconductor layer 120, respectively. A first organic insulating layer 170 may be disposed on the source electrode 160 and the drain electrode 162. The first organic insulating layer 170 may include an organic insulating material. The storage capacitor Cst may include at least two capacitor electrodes overlapping each other in a plan view, and in an embodiment, FIG. 8 shows a first capacitor electrode on the same layer as the first semiconductor layer 120, a second capacitor electrode on the same layer as the first gate electrode 140, and a third capacitor electrode on the same layer as the source electrode 160 and/or the drain electrode 162. The source electrode 160 and/or the drain electrode 162 may each include aluminum (Al), copper (Cu), and/or titanium (Ti), and include a single layer or a multi-layer including the above materials.

A connection metal CM may be disposed on the first organic insulating layer 170 and may electrically connect the pixel driving circuit PC and a pixel electrode 210 of the light-emitting diode LED to each other. The pixel electrode 210 of the light-emitting diode LED may be connected to the connection metal CM through a contact hole formed in a second organic insulating layer 190. The first organic insulating layer 170 and/or the second organic insulating layer 190 may include an organic insulating material such as benzocyclobutene (BCB), polyimide, or hexamethyldisiloxane (HMDSO). The connection metal CM may include aluminum (Al), copper (Cu), and/or titanium (Ti), and include a single layer or a multi-layer including the above materials.

In another embodiment, the pixel electrode 210 of the light-emitting diode LED may be directly and electrically connected to the pixel driving circuit PC. In another embodiment, a third organic insulating layer additionally disposed on the second organic insulating layer 190 may be further disposed between the pixel electrode 210 of the light-emitting diode LED and the pixel driving circuit PC, and in this case, the pixel electrode 210 of the light-emitting diode LED and the pixel driving circuit PC may be electrically connected to each other through a plurality of connection metals.

The light-emitting diode OLED may have a stack structure of the pixel electrode 210, an intermediate layer 220, and an opposite electrode 1230. The pixel electrode 210 of the light-emitting diode LED may be disposed on an organic insulating layer, for example, the second organic insulating layer 190.

The pixel electrode 210 may include metal and/or a conductive oxide. As an example, the pixel electrode 210 may include a reflective layer and a layer disposed on and/or under the reflective layer, wherein the reflective layer includes silver (Ag), an alloy containing silver, molybdenum (Mo), an alloy containing molybdenum, aluminum (Al), an alloy containing aluminum, aluminum nitride (AlN_{X}), tungsten (W), tungsten nitride (WN_{X}), copper (Cu), nickel (Ni), chrome (Cr), chrome nitride (CrN_{X}), titanium (Ti), tantalum (Ta), platinum (Pt), or a compound thereof, and the layer includes indium tin oxide (ITO), indium zinc oxide (IZO), or indium oxide (In₂O₃). In an embodiment, the pixel electrode 210 may have a three-layered structure of an ITO layer, an Ag layer, and an ITO layer that are sequentially stacked.

The bank layer 300 may be disposed on the pixel electrode 210. The bank layer 300 may include a first layer 310 including metal, and a second layer 320 disposed on the first layer 310. Because the first layer 310 of the bank layer 300 may include metal and the metal has conductivity, an insulating layer, for example, an inorganic insulating layer 115 may be disposed between the pixel electrode 210 and the bank layer 300. The inorganic insulating layer 115 may include an inorganic insulating material such as silicon nitride, silicon oxynitride, and silicon oxide, and include a single-layered structure or a multi-layered structure including the above inorganic insulating materials.

The first layer 310 of the bank layer 300 may include a conductive material, for example, metal. The first layer 310 may include silver (Ag), an alloy containing silver, molybdenum (Mo), an alloy containing molybdenum, aluminum (Al), an alloy containing aluminum, aluminum nitride (AlN_{X}), tungsten (W), tungsten nitride (WN_{X}), copper (Cu), nickel (Ni), chrome (Cr), chrome nitride (CrN_{X}), titanium (Ti), tantalum (Ta), platinum (Pt), or a compound thereof, and the layer includes indium tin oxide (ITO), indium zinc oxide (IZO), or indium oxide (In₂O₃).

The second layer 320 of the bank layer 300 may include an inorganic material, for example, a conductive inorganic material or an insulating inorganic material. In an embodiment, the second layer 320 of the bank layer 300 may include silver (Ag), an alloy containing silver, molybdenum (Mo), an alloy containing molybdenum, aluminum (Al), an alloy containing aluminum, aluminum nitride (AlN_{X}), tungsten (W), tungsten nitride (WN_{X}), copper (Cu), nickel (Ni), chrome (Cr), chrome nitride (CrN_{X}), titanium (Ti), tantalum (Ta), platinum (Pt), or a compound thereof, and include a different metal from the first layer 310. In another embodiment, the second layer 320 of the bank layer 300 may include an inorganic insulating material such as silicon nitride, silicon oxynitride, and silicon oxide.

The bank layer 300 may define therein the first openings 300OP1 and the second openings 300OP2 passing through the bank layer 300 in a thickness direction (e.g., a z direction) of the bank layer 300. Each of the first openings 300OP1 and the second openings 300OP2 may pass through the first layer 310 and the second layer 320 of the bank layer 300. The first opening 300OP1 may overlap the pixel electrode 210 in a plan view, and the second opening 300OP2 may be disposed around the first opening 300OP1 and may at least partially surround the first opening 300OP1 in a plan view. The intermediate layer 220 may overlap the pixel electrode 210 through the first opening 300OP1 of the bank layer 300 in a plan view. The intermediate layer 220 may include an emission layer, and the emission layer may include a polymer organic material or a low-molecular weight organic material emitting red, green, or blue light. The intermediate layer 220 may include functional layers that may be disposed on and under the emission layer. The functional layers may include at least one selected from a hole transport layer (HTL), a hole injection layer (HIL), an electron transport layer (ETL), and an electron injection layer (EIL).

The opposite electrode 1230 may be disposed on the intermediate layer 220 and may include a conductive material having a low work function. The opposite electrode 1230 may include a (semi) transparent layer including silver (Ag), magnesium (Mg), aluminum (Al), platinum (Pt), palladium (Pd), gold (Au), nickel (Ni), neodymium (Nd), and iridium (Ir), chromium (Cr), lithium (Li), calcium (Ca), or an alloy thereof. The opposite electrode 1230 may further include a layer on the (semi) transparent layer, the layer including ITO, IZO, ZnO, or In₂O₃.

The opposite electrode 1230 may be in direct contact with the first layer 310 of the bank layer 300. As an example, the edge portion of the opposite electrode 1230 may be in direct contact with the lateral surface of the first layer 310 facing the first opening 300OP1 and be electrically connected to the first layer 310.

The second layer 320 of the bank layer 300 may include a first protrusion tip PT1 extending toward the second opening 300OP2. The first protrusion tip PT1 may extend from a first point at which the lateral surface of the first layer 310 facing the second opening 300OP2 meets the bottom surface of the second layer 320, and extend to have a first length L1 in a direction away from the first point.

A second protrusion tip PT2 may be disposed under the second opening 300OP2 of the bank layer 300. In an embodiment, an inorganic layer, for example, an inorganic insulating layer 115 disposed between the second organic insulating layer 190 and the bank layer 300 may include the second protrusion tip PT2 extending on a concave portion 190G to form an eaves structure. The second protrusion tip PT2 may extend from a second point at which the lateral surface of the second organic insulating layer 190 facing the concave portion 190G meets the bottom surface of the inorganic insulating layer 115, and extend to have a second length L2 in a direction away from the second point. The second length L2 may be less than the first length L1. As an example, the second length L2 may be 0.5 micrometers (µm) or less, and the first length L1 may be about 0.5 µm to about 1 µm.

The concave portion 190G of the second organic insulating layer 190 overlaps the second opening 300OP2 of the bank layer 300 in a plan view. A depth dp of the concave portion 190G may be less than a thickness t1 of the second organic insulating layer 190. A depth dp of the concave portion 190G may be less than a thickness t2 of the first layer 310 of the bank layer 300. Here, the thicknesses are measured in the z direction.

Due to the first protrusion tip PT1, the second opening 300OP2 of the bank layer 300 may have an undercut structure or an eaves structure (referred to as a first eaves structure, hereinafter), and due to the second protrusion tip PT2, the concave portion 190G of the second organic insulating layer 190 may have an undercut structure or an eaves structure (referred to as a second eaves structure, hereinafter). The intermediate layer 220 of the light-emitting diode LED may be formed by an evaporation deposition method, and during the process of forming the intermediate layer 220, a material corresponding to the intermediate layer 220 may be deposited by being separated into a plurality of portions through a double structure of the first and second protrusion tips PT1 and PT2, for example, the first and second eaves structures. In this regard, it is shown in FIGS. 8 and 9 that dummy intermediate layers 220D, 220D', and 220D'' including the same material as the intermediate layer 220 are separated and disposed on the upper surface of the first protrusion tip PT1 of the second layer 320, the upper surface of the second protrusion tip PT2 of the inorganic insulating layer 115, and the bottom surface of the concave portion 190G, respectively.

Unlike FIGS. 8 and 9, in the case where the dummy intermediate layers 220D, 220D', and 220D'' including an organic material are continuously formed, foreign substance such as moisture may penetrate the light-emitting diode LED through the first bridge portion 12 spatially connected to the outside of the display device 1 to damage the light-emitting diode LED. In contrast, according to an embodiment of the present disclosure, progression of moisture due to the dummy intermediate layers 220D, 220D', and 220D'' including an organic material may be prevented while maximally utilizing a space through the double structure of the first and second protrusion tips PT1 and PT2.

In an embodiment, the second layer 320 of the bank layer 300 may include a third protrusion tip PT3 extending toward the first opening 300OP1. The third protrusion tip PT3 may extend from a third point at which the lateral surface of the first layer 310 facing the first opening 300OP1 meets the bottom surface of the second layer 320, and extend to have a third length L3 in a direction away from the third point. The third length L3 may be greater than the second length L2 and be substantially the same as the first length L1. Here, the lengths L1, L2, and L3 may be measured in a direction intersecting (e.g., substantially perpendicular to) the thickness direction (e.g., a z direction) of the display device 1.

The display device 1 may be configured to separate the intermediate layer 220 on the pixel electrode 210 from the dummy intermediate layers 220D, 220D', and 220D'' through the structure of the third protrusion tip PT3. Accordingly, the effect of preventing damage to the light-emitting diode LED due to moisture may be improved even more.

During the process of forming the opposite electrode 1230, a dummy opposite electrode 230D' may be formed in the second opening 300OP2. The opposite electrode 1230 may be formed through a process such as sputtering, and the dummy opposite electrode 230D' may continuously extend within the second opening 300OP2. As an example, the dummy opposite electrode 230D' may extend to continuously cover (or overlap) the upper surface, the lateral surface, and the lower surface of the second protrusion tip PT2, and cover (or overlap) each of the dummy intermediate layers 220D' and 220D'' disposed on the upper surface of the second protrusion tip PT2 and in the concave portion 190G. The edge portion of the dummy opposite electrode 230D' may be in direct contact with the lateral surface of the first layer 310 facing the second opening 300OP2 and be electrically connected to the first layer 310.

During the process of forming the opposite electrode 1230, a material forming the opposite electrode 1230 may be formed also on the second layer 320 of the bank layer 300. In this regard, FIGS. 8 and 9 show the dummy opposite electrode 230D disposed on the second layer 320 of the bank layer 300. Because the depth dp of the concave portion 190G corresponding to the height of the second eaves structure is less than the thicknesst2 of the first layer 310 of the bank layer 300 corresponding to the height of the first eaves structure, the dummy opposite electrode 230D on the upper surface of the second layer 320 of the bank layer 300 and the dummy opposite electrode 230D' disposed inside the second opening 300OP2 are separated from each other, but the dummy opposite electrode 230D' disposed inside the second opening 300OP2 may be continuously connected without being separated by the second protrusion tip PT2.

The display device 1 may be configured to separate the opposite electrode 1230 on the pixel electrode 210 from the dummy opposite electrodes 230D and 230D' through the structure of the third protrusion tip PT3. Accordingly, moisture may be prevented from penetrating through a contact surface of the dummy opposite electrode 230D and 230D' and the dummy intermediate layer 220D, 220D', and 220D'', and the effect of preventing damage to the light-emitting diode LED may be improved even more.

The encapsulation layer 400 may include one or more inorganic encapsulation layers, and in this regard, it is shown in FIGS. 8 and 9 that the encapsulation layer 400 includes first and second inorganic encapsulation layers 410 and 430. The first and second inorganic encapsulation layer 410 and 430 may each include an inorganic insulating material such as silicon nitride, silicon oxynitride, and silicon oxide, and include a single layer or a multi-layer including the above inorganic insulating materials.

Although not shown in FIGS. 8 and 9, an organic encapsulation layer may be disposed between the first and second inorganic encapsulation layers 410 and 430 in an embodiment. The organic encapsulation layer may overlap the first opening 300OP1 of the bank layer 300 but may not overlap the second opening 300OP2 in a plan view. In another embodiment, the organic encapsulation layer may overlap the first opening 300OP1 and the second opening 300OP2 of the bank layer 300 in a plan view. As shown in FIG. 9, the bank layer 300 may include a portion (referred to as a first portion, hereinafter) disposed in the first bridge portion 12, and the first portion of the bank layer 300 may connect portions (referred to as second portions, hereinafter) of the bank layer 300 to each other, the second portions being located in first island portions 11 disposed on two opposite sides of the first bridge portion 12, respectively. The opposite electrode 1230 of the light-emitting diode LED disposed in one of the first island portions 11 may be electrically connected to the opposite electrode 1230 of the light-emitting diode LED disposed in one of the first island portions 11 through a contact structure of the opposite electrode 1230, the first layer 310, and the dummy opposite electrode 230D', and the connection structure of the second portion of the bank layer 300.

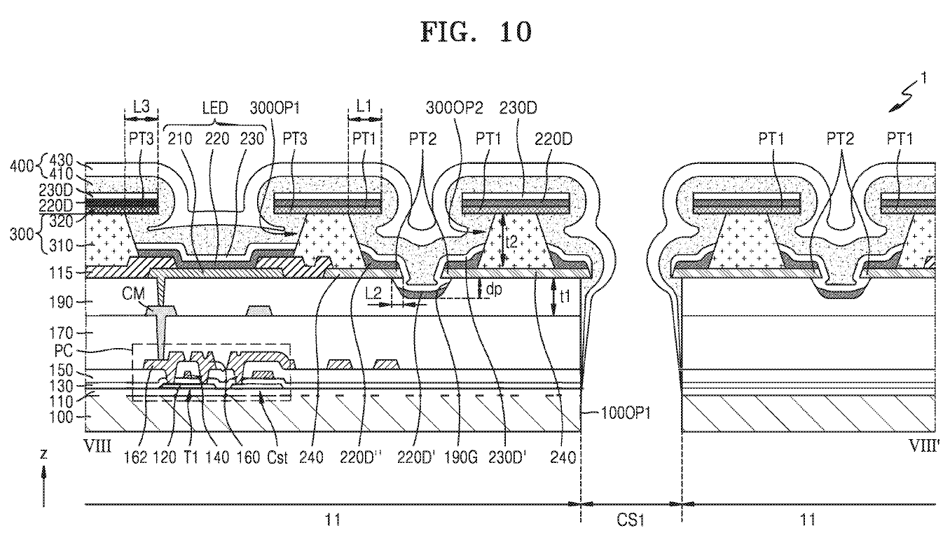

FIG. 10 is a cross-sectional view of a portion of the display device 1, taken along line VIII-VIII' of FIG. 7, according to an embodiment.

The structure of the display device 1 shown in FIG. 10 is substantially the same as the embodiment described with reference to FIG. 8 and is different from the embodiment in the material of the inorganic material of the second protrusion tip PT2. In the embodiment shown in FIG. 8, the inorganic layer between the second organic insulating layer 190 and the bank layer 300 is a layer including an insulating inorganic material, and in this regard, it is shown that the inorganic material is the inorganic insulating layer 115. In another embodiment, the inorganic layer includes a conductive inorganic material, and in this regard, FIG. 10 is different in that the inorganic layer includes an inorganic conductive layer 240. Hereinafter, for convenience of description, differences are mainly described.

Referring to FIG. 10, the inorganic conductive layer 240 as an inorganic layer may be disposed between the second organic insulating layer 190 and the bank layer 300. The inorganic conductive layer 240 may include the second protrusion tip PT2 extending on the concave portion 190G.

The inorganic conductive layer 240 may include the second protrusion tip PT2 extending on the concave portion 190G to form an eaves structure. The second protrusion tip PT2 may extend from a second point at which the lateral surface of the second organic insulating layer 190 facing the concave portion 190G meets the bottom surface of the inorganic insulating layer 115, and extend to have a second length L2 in a direction away from the second point. The second length L2 may be less than the first length L1.

The inorganic conductive layer 240 may include a conductive material, for example, metal and/or a metal oxide. As an example, the inorganic conductive layer 240 may include silver (Ag), an alloy containing silver, molybdenum (Mo), an alloy containing molybdenum, aluminum (Al), an alloy containing aluminum, aluminum nitride (AlN_{X}), tungsten (W), tungsten nitride (WN_{X}), copper (Cu), nickel (Ni), chrome (Cr), chrome nitride (CrN_{X}), titanium (Ti), tantalum (Ta), platinum (Pt), or a compound thereof, and the layer includes indium tin oxide (ITO), indium zinc oxide (IZO), or indium oxide (In₂O₃). In an embodiment, the inorganic conductive layer 240 may include the same material as the pixel electrode 210 and have the same stack structure as the pixel electrode 210. As an example, the inorganic conductive layer 240 may have a three-layered structure of an ITO layer, an Ag layer, and an ITO layer that are sequentially stacked.

The inorganic conductive layer 240 may be electrically connected to the bank layer 300. The first layer 310 of the bank layer 300 may be in direct contact with the upper surface of the inorganic conductive layer 240. The edge (e.g., an opposite edge of the second protrusion tip PT2) of the inorganic conductive layer 240 may be covered by the inorganic insulating layer 115.

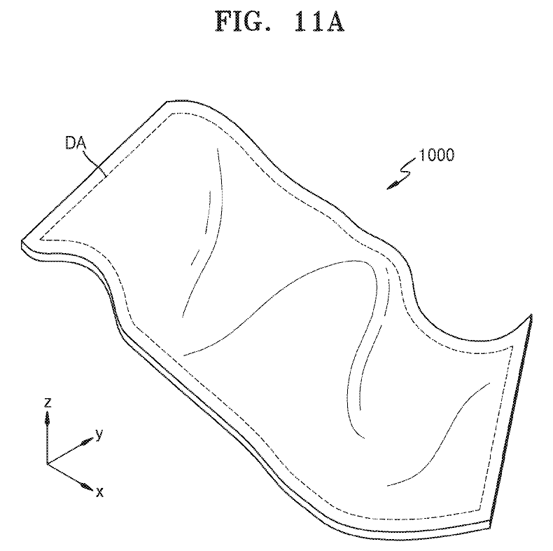

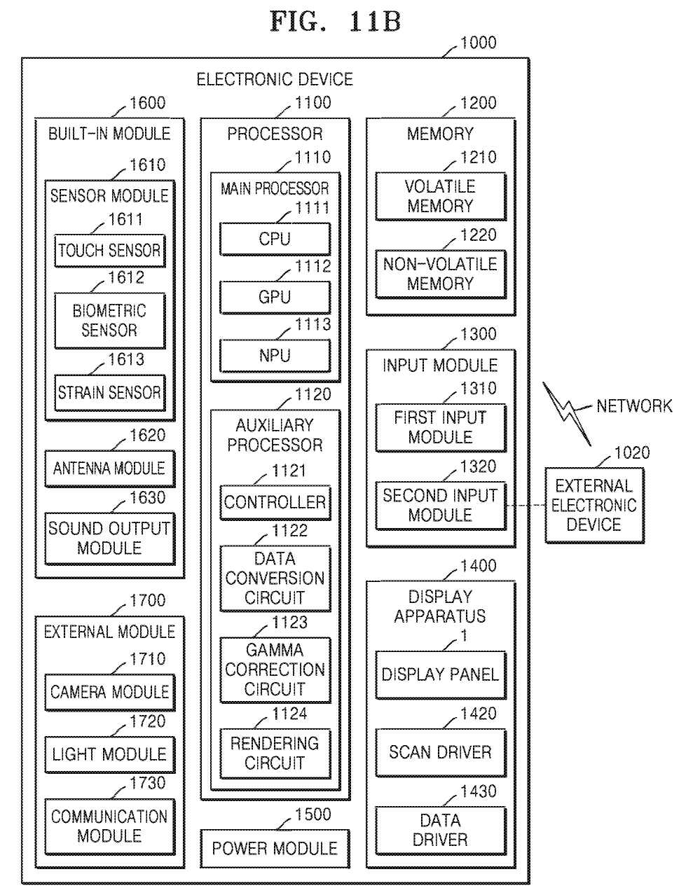

FIG. 11A is a schematic perspective view of an electronic apparatus 1000 including the display device according to an embodiment, and FIG. 11B is a schematic block diagram of the electronic apparatus 1000 including the display device 1 according to an embodiment.

Referring to FIG. 11A, the electronic apparatus 1000 is freely deformed three-dimensionally, and may provide a three-dimensional image surface through the display area DA. When the electronic apparatus 1000 is freely deformed three-dimensionally, it is distinguished from an operation of an electronic apparatus having a rollable display device such as a case where a portion of a rolled-up display area is visible to a user and then another portion of the rolled-up display area is unfolded so that the entire display area is visible to the user (or a case where the entire unfolded display area is visible to the user and then the display area is rolled-up so that only a portion of the display area is visible to the user). The electronic apparatus 1000 according to embodiments of the present disclosure may represent deformation such as a case where the area of the entire display area DA increases or decreases again while the electronic apparatus 1000 is deformed in the x direction, y direction, and/or z direction.

Referring to FIG. 11B, the electronic apparatus 1000 may include a processor 1100, a memory 1200, an input module 1300, a display module 1400, a power module 1500, a built-in module 1600, and an external module 1700. According to an embodiment, in the electronic apparatus 1000, at least one of the elements may be omitted, or one or more other elements may be added. According to an embodiment, some (e.g., the built-in module 1600) of the elements may be integrated into another element (e.g., the display module 1400).

The processor 1100 may control at least one other element (e.g., a hardware or software element) of the electronic apparatus 1000 connected to the processor 1100 by executing software, and perform various data processes or operations. According to an embodiment, as at least some of data processes or operations, the processor 1100 may store commands or data received from another element (e.g., the input module 1300, a sensor module 1610, or a communication module 1730) in a volatile memory 1210, process the commands or data stored in the volatile memory 1210, and store result data in a non-volatile memory 1220.

The processor 1100 may include a main processor 1110 and an auxiliary processor 1120. The main processor 1110 may include at least one of a central processing unit (CPU) 1111 and an application processor (AP). The main processor 1110 may further include at least one of a graphics processing unit (GPU) 1112, a communication processor (CP), and an image signal processor (ISP). The main processor 1110 may further include a neural processing unit (NPU) 1113. The NPU is a processor specialized in processing artificial intelligence models, and the artificial intelligence models may be created through machine learning. The artificial intelligence models may include a plurality of artificial neural network layers. The artificial neural network may be one of a deep neural network (DNN), a convolutional neural network (CNN), a recurrent neural network (RNN), a restricted Boltzmann machine (RBM), a deep belief network (DBN), a bidirectional recurrent deep neural network (BRDNN), a deep Q-network, and a combination of two or more of the above, but is not limited to the examples described above. The artificial intelligence models may additionally or alternatively include a software structure in addition to a hardware structure. At least two of the processing units and the processors may be implemented as one integrated construction (e.g., a single chip) or implemented as independent constructions (e.g., a plurality of chips), respectively.

The auxiliary processor 1120 may include a controller 1121. The controller 1121 may include an interface conversion circuit and a timing control circuit. The controller 1121 receives image signals from the main processor 1110, converts a data format of image signals to match interface specifications of the display module 1400, and outputs image data. The controller 1121 may output various kinds of control signals for driving the display module 1400.

The auxiliary processor 1120 may further include a data processing circuit such as a data conversion circuit 1122, a gamma correction circuit 1123, and a rendering circuit 1124. The data conversion circuit 1122 may receive image data from the controller 1121, correct image data such that images are displayed at desired brightness according to characteristics of the electronic apparatus 1000, a user’s settings, or the like, or convert image data to reduce power consumption or compensate for an afterimage. The gamma correction circuit 1123 may convert image data, a gamma reference voltage, or the like such that images displayed by the electronic apparatus 1000 have desired gamma characteristics. The rendering circuit 1124 may receive image data from the controller 1121, and render the image data by taking into account the pixel configuration of the display device 1 applied to the electronic apparatus 1000. At least one of the data conversion circuit 1122, the gamma correction circuit 1123, and the rendering circuit 1124 may be integrated into another element (e.g., the main processor 1110 or the controller 1121). In an embodiment, the auxiliary processor 1120 may be integrated into a data driver 1430.

The memory 1200 may store various data and input data or output data for commands related thereto, wherein the various data are used by at least one element (e.g., the processor 1100 or the sensor module 1610) of the electronic apparatus 1000. The memory 1200 may include at least one of the volatile memory 1210 and the non-volatile memory 1220.

The input module 1300 may receive commands or data from the outside (e.g., a user or an external electronic apparatus 2000) of the electronic apparatus 1000, wherein the commands or data are to be used by the element (e.g., the processor 1100, the sensor module 1610, or a sound output module 1630) of the electronic apparatus 1000.

The input module 1300 may include a first input module 1310 to which commands or data from a user are input, and a second input module 1320 to which commands or data from the external electronic apparatus 2000 are input.

The first input module 1310 may include a microphone, a mouse, a keyboard, or a pen (e.g., a passive pen or active pen). The first input module 1310 may include a mechanical input means such as buttons, a dome switch, a jog wheel, a jog switch, and the like, or a touch input means located on the lower surface or the lateral surface of the electronic apparatus 1000. The touch input means may include a touchscreen layer of the display device 1.

The second input module 1320 may be connected to various kinds of external electronic apparatuses 2000 connected to the electronic apparatus 1000 via wires or wirelessly. In an embodiment, the second input module 1320 may include a high-definition multimedia interface (HDMI), a universal serial bus (USB) interface, a secure digital (SD) card interface, or an audio interface. The second input module 1320 may include a connector that may physically connect the electronic apparatus 1000 to the external electronic apparatus 2000, wherein the connector includes an HDMI connector, a USB connector, an SD card connector, or an audio connector (e.g., a headphone connector). The electronic apparatus 1000 may perform appropriate control related to the connected external electronic apparatus 2000 in response to the external electronic apparatus 2000 being connected to the second input module 1320.

The display module 1400 provides a user with visual information. The display module 1400 may include the display device 1, a scan driver 1420, and the data driver 1430.

The display device 1 displays (outputs) information processed by the electronic apparatus 1000. The display device 1 may display execution screen information of an application driven in the electronic apparatus 1000, or user interface (UI) and graphic user interface (GUI) information corresponding to the execution screen information.

The scan driver 1420 may be mounted on the display device 1 as a driving chip. Alternatively, the scan driver 1420 may be directly disposed on the display device 1. As an example, the scan driver 1420 may include an amorphous silicon thin-film transistor (TFT) gate driver circuit (ASG), a low temperature polycrystalline silicon (LTPS) TFT gate driver circuit, or an oxide semiconductor TFT gate (OSG) driver circuit embedded in the display device 1. The scan driver 1420 receives control signals from the controller 1121 and outputs scan signals to the display device 1 in response to control signals.

The display device 1 may further include an emission control driver. The emission control driver outputs an emission control signal to the display device 1 in response to a control signal received from the controller 1121. The emission control driver may be formed separately from the scan driver 1420 or integrated in the scan driver 1420.

The data driver 1430 receives a control signal from the controller 1121, converts image data into a data voltage in the form of an analog voltage in response to a control signal, and outputs data voltages to the display device 1.

The data driver 1430 may be integrated into some elements of the auxiliary processor 1120. As an example, the data driver 1430 may be provided in a timing controller embedded driver IC including the controller 1121.

The data driver 1430 may be mounted on the display device 1 as a driving chip. Alternatively, the data driver 1430 may be directly disposed on the display device 1. In the case where the scan driver 1420 and the data driver 1430 are directly disposed on the display device 1, the display device 1 may be actually the display module 1400.

The power module 1500 supplies power to the elements of the electronic apparatus 1000. The power module 1500 may include a battery charging a power voltage. In addition, the power module 1500 has a connection port, and the connection port may be included in the second input module 1320 to which an external charger that supplies power to charge the battery is connected. Alternatively, the power module 1500 may include a wireless power transmission/reception member to charge the battery wirelessly. The wireless power transmission/reception member may include a plurality of coil-shaped antenna radiators. The power module 1500 may include a power management integrated circuit (PMIC). The PMIC supplies power optimized for each of the elements of the electronic apparatus 1000.

The electronic apparatus 1000 may further include the built-in module 1600 and the external module 1700. The built-in module 1600 may include the sensor module 1610, an antenna module 1620, and the sound output module 1630. The external module 1700 may include a camera module 1710, a light module 1720, and/or the communication module 1730.

The sensor module 1610 may include touch electrodes of the touchscreen layer of the display device 1, and a touch sensor driver. The sensor module 1610 may sense an input due to a user’s body or an input due to a pen, and generate an electrical signal or a data value corresponding to the input. The sensor module 1610 may include at least one of a touch sensor 1611, a biometric sensor 1612, and a strain sensor 1613.

The touch sensor 1611 may generate a data value corresponding to coordinate information of an input due to a user’s body (e.g., fingers and the like) or an input due to a pen. The touch sensor 1611 may generate, as data values, changes in electrostatic capacity, pressure, or electromagnetism due to an input.

The biometric sensor 1612 may generate data values that recognize a portion of the user's body (e.g., fingerprints, irises, face, and the like) or generate data values corresponding to body information (e.g., blood pressure, moisture, heart rate, body composition, and the like). The biometric sensor 1612 may use an optical method, an ultrasonic method, or a capacitive method.

The strain sensor 1613 may include layers, patterns or wirings in which a measurable physical quantity changes according to the stretching of the display device 1. As an example, the strain sensor 1613 may include layers, patterns or wirings in which a pressure, a resistance, and/or a capacitance changes due to the stretching of the display device 1. In another embodiment, the strain sensor 1613 may include optical layers or optical patterns in which a light transmittance and/or reflectivity changes due to the stretching of the display device 1.

The electronic apparatus 1000 may improve the quality of images implemented by the display device 1 or control the display device 1 based on physical quantity changes due to the stretching of the display device 1 measured by the strain sensor 1613. Control operations of the display device 1 may include operations such as displaying an operation image for protecting the display device 1, blocking voltages for driving the display device 1, or stopping a stretching operation of the display device 1.

In an embodiment, at least one of the touch sensor 1611, the biometric sensor 1612, and the strain sensor 1613 may be built into the display device 1. As an example, at least one of the touch sensor 1611, the biometric sensor 1612, and the strain sensor 1613 may be formed during a process that is successive to the process of forming the pixel driving circuit portion and/or the light-emitting element of the display device 1. Accordingly, the display device 1 may serve as one of the input modules 1300 that provide an input interface between the electronic apparatus 1000 and a user, and simultaneously, serve as the display module 1400 that provides an output interface between the electronic apparatus 1000 and a user.

In an embodiment, at least two of the touch sensor 1611, the biometric sensor 1612, and the strain sensor 1613 may be formed to be integrated in one sensing panel through the same process. In an embodiment, although the sensing panel may be disposed between the display device 1 and a window cover disposed on a front surface of the display device 1, the present disclosure is not limited thereto.

The antenna module 1620 may include one or more antennas for transmitting signals or power to the outside or receiving signals or power from the outside. In an embodiment, the communication module 1730 may transmit signals to an external electronic apparatus or receive signals from an external electronic apparatus through an antenna suitable for a communication method. An antenna pattern of the antenna module 1620 may be integrated in one element (e.g., the display device 1) of the display module 1400 or the sensor module 1610.

The sound output module 1630 is a device for outputting sound signals to the outside of the electronic apparatus 1000, and may output sound data received from the communication module 1730 or stored in the memory 1200 during call signal reception, a communication mode or recording mode, a voice recognition mode, a broadcasting reception mode, and the like. The sound output module 1630 may output sound signals related to a function (e.g., call signal reception tone, a message reception tone, and the like) performed by the electronic apparatus 1000. The sound output module 1630 may include a receiver and a speaker. At least one of the receiver and the speaker may be a sound generator that is attached on the back side of the display device 1 and vibrates the display device 1 to output sounds. The sound generator may be a piezoelectric element or a piezoelectric actuator that contracts and expands according to electrical signals, or an exciter that generates magnetic force by using a voice coil to vibrate the display device 1.

The camera module 1710 may capture still images and moving images. In an embodiment, the camera module 1710 may include one or more lenses, an image sensor, or an image signal processor. The camera module 1710 may further include an infrared camera that may measure whether a user is present, a user’s position, a user’s gaze, and the like.

The light module 1720 may output signals for informing occurrence of an event using light of a light source, or provide light to obtain images. Here, examples of event occurrence include message reception, call signal reception, a missed call, an alarm, a calendar reminder, receiving an email, being notified of battery charge information, and the like. The light module 1720 may include a light-emitting diode or a xenon lamp. The light module 1720 may emit light of a single color or multiple colors to the front side or back side of the electronic apparatus 1000. The light module 1720 may operate in cooperation with the camera module 1710 or independently.

The communication module 1730 may establish a wired or wireless communication channel between the electronic apparatus 1000 and the external electronic apparatus 2000, and perform communication through the established communication channel. The communication module 1730 may include one or both of a wireless communication module, such as a cellular communication module, a short-range wireless communication module, or a global navigation satellite system (GNSS) communication module, and a wired communication module, such as a local area network (LAN) communication module, or a power line communication module. The communication module 1730 may transmit and receive wireless signals on the Internet using at least one of a wireless LAN) (WLAN), wireless-fidelity (Wi-Fi), Wi-Fi direct, and digital living network alliance (DLNA) technologies. In addition, the communication module 1730 may support short-range communication using at least one of Bluetooth™, RFID radio frequency identification (RFID), infrared data association (IrDA), ultra-wideband (UWB), ZigBee, near field communication (NFC), Wi-Fi, Wi-Fi Direct, and wireless universal serial bus (USB) technologies. The above-described various kinds of communication modules 1730 may be implemented in one chip or implemented as separate chips, respectively.

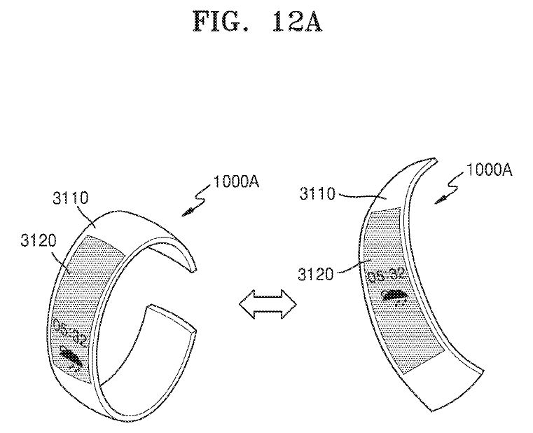

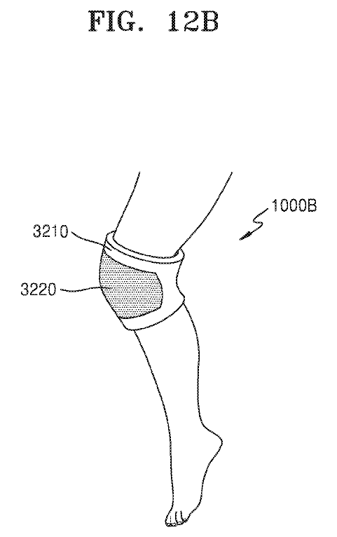

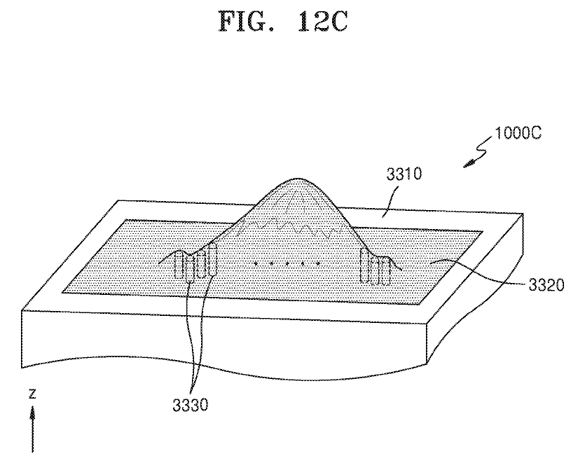

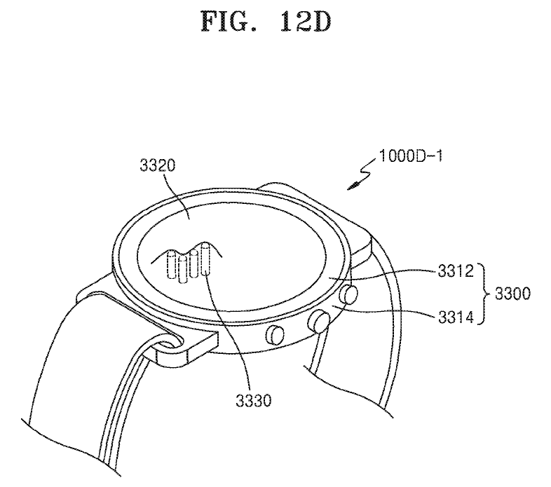

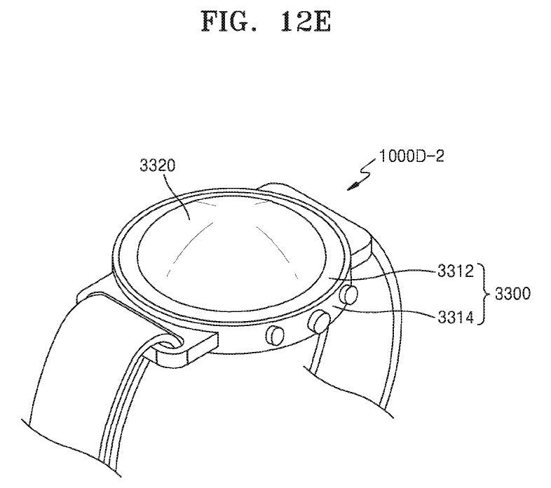

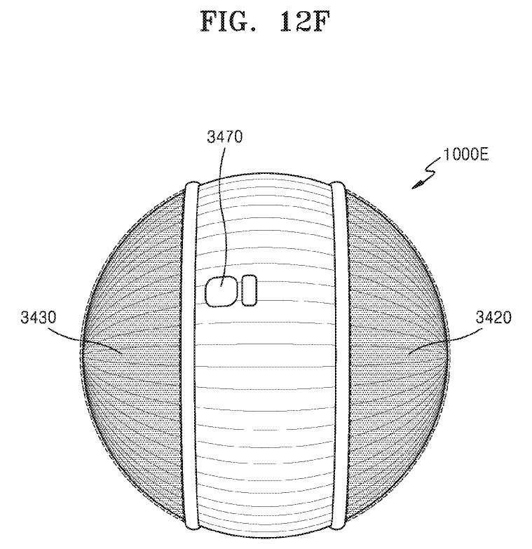

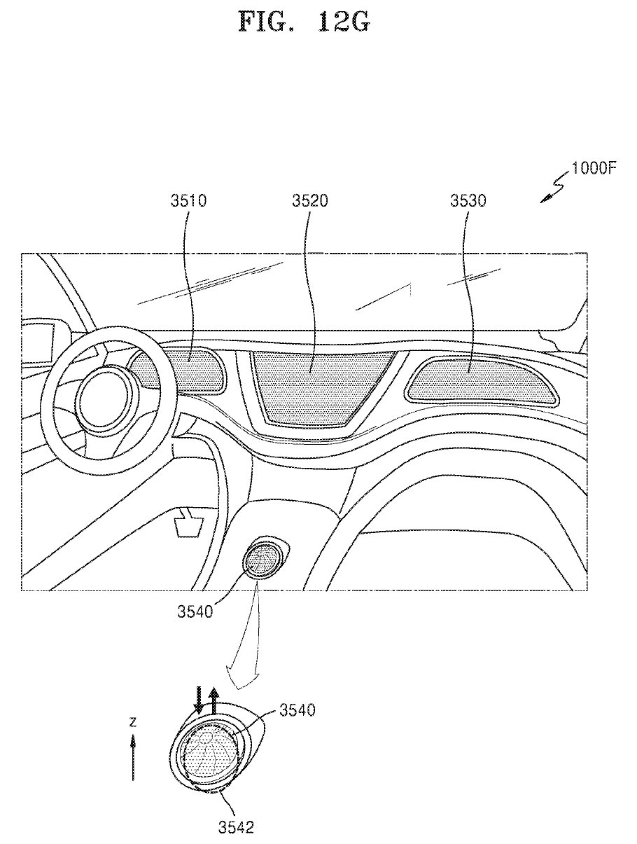

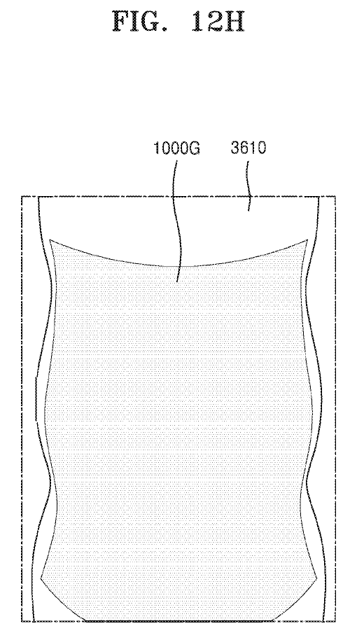

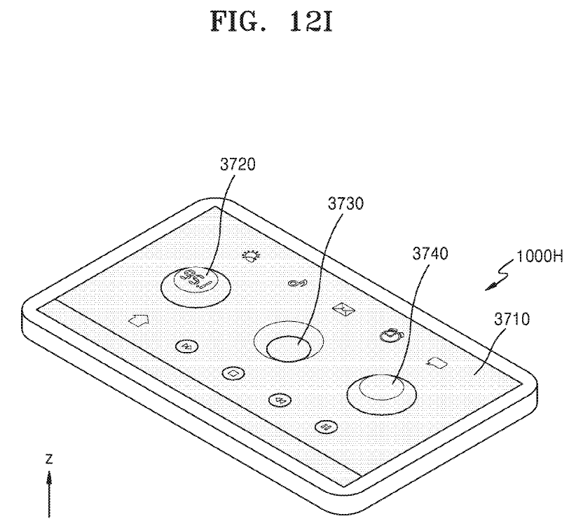

FIGS. 12A-12I are schematic perspective views of an electronic apparatus including a display device according to an embodiment, respectively.

Referring to FIG. 12A, the display device according to an embodiment of the present disclosure may be utilized in a wearable electronic apparatus 1000A that may be worn on a portion of a user's body. The wearable electronic apparatus 1000A may include a body portion 3110 and a display portion 3120 provided to the body portion 3110. The display device according to embodiments may be used as the display portion 3120 of the wearable electronic apparatus 1000A. As shown in FIG. 12A, the wearable electronic apparatus 1000A may be deformed. In an embodiment, the wearable electronic apparatus 1000A may be used as a smartwatch or a smartphone according to a user’s selection.

FIG. 12B shows a medical electronic apparatus 1000B. In an embodiment, the medical electronic apparatus 1000B may include a body portion 3210 and a light-emitting portion 3220. The display device according to embodiments of the present disclosure may be used as the light-emitting portion 3220 of the medical electronic apparatus 1000B. The light-emitting portion 3220 may emit light (e.g., infrared rays, visible rays, and the like) in a preset wavelength band to a patient’s body. In an embodiment, the body portion 3210 may include a stretchable fiber material and have a structure that may be worn on the body of a user.

FIG. 12C shows an educational electronic apparatus 1000C. In an embodiment, the educational electronic apparatus may include a display portion 3320 provided inside a housing 3310. The display portion 3320 may be used as the display device according to the embodiments of the present disclosure. An image such as the sea with crashing waves, a snow-covered mountain, or a volcano with flowing lava can be provided through the display portion 3320, and in this case, the display portion 3320 may be stretched in a height direction (e.g., a z direction) to reflect the height of the wave, mountain, or volcano. In an embodiment, a portion of the display portion 3320 may be configured to sequentially change its height in a direction in which the lava flows, thereby showing the movement of the lava three dimensionally. The educational electronic apparatus 1000C may include a plurality of pins 3330 (or strokes) disposed on the rear surface of the display portion 3320 such that the display portion 3320 is stretched in the height direction. The pins 3330 may be implemented to move in the third direction (e.g., a z direction or a -z direction) such that an image expressed on the display portion 3320 has a height three dimensionally. Although FIG. 12C describes the educational electronic apparatus 1000C, the purpose thereof is not limited thereto as far as the educational electronic apparatus provides preset image information.

FIGS. 12D and 12E show the display device is used in wearable electronic apparatuses 1000D-1 and 1000D-2 such as a smartwatch.

In an embodiment, as shown in FIG. 12D, because the display device corresponding to the display portion 3320 of the electronic apparatus 1000D-1 is stretchable three-dimensionally, the display panel may provide, to a user, various haptic information in addition to visual information through images. In an embodiment, the electronic apparatus 1000D-1 may provide haptic information, such as Braille display for the visually impaired or tactile stimulation linked to an image, by using a plurality of pins 3330 (or stroke portions) disposed below the display portion 3320. Because the display panel forming the display portion 3320 is stretchable three-dimensionally, the display device may provide the haptic information to a user. The electronic apparatus 1000D-1 may include a body portion 330, wherein the body portion 330 includes a housing 3314 in which the display device forming the display portion 3320 and the pins 3330 (or stroke portions) are accommodated, and a frame 3312 that may be coupled to the housing 3314 with the display device therebetween. In an embodiment, the frame 3312 may be integrally formed with the housing 3314.

The electronic apparatus 1000D-2 of FIG. 12E may include the body portion 330 and the display portion 3320 accommodated in the body portion 330 and providing visual information as in FIG. 12D. In an embodiment, because the display device corresponding to the display portion 3320 is stretchable three-dimensionally, the display device may include the display portion 3320 of a dome shape. In an embodiment, the display device may be assembled to the body frame of a dome shape during the process of manufacturing the electronic apparatus 1000D-2, and in this case, because the display device is stretchable three-dimensionally, the display device may be assembled while being stretched along the shape of the hemispherical body frame.

FIG. 12F shows an electronic apparatus 1000E according to an embodiment includes a robot. The robot may recognize a movement or object using a camera module 3470 and display preset images to a user through display portions 3420 and 3430.

In an embodiment, because the display devices according to an embodiment may be stretched in various directions as described above, the display devices may be assembled to the body frame having a hemispherical shape, and thus, the robot may include the display portions 3420 and 3430 of a hemispherical shape.

FIG. 19G shows a vehicle display device 1000F as an electronic apparatus according to an embodiment. The vehicle display device 1000F may include a cluster 3510, a center information display (CID) 3520, and/or a co-driver display 3530. Because the display device according to an embodiment may be stretched in various directions, the display device may be used in the cluster 3510, the CID 3520, and/or the co-driver display 3530 without being restricted by the shape of an internal frame of the vehicle.

Although it is shown in FIG. 12H that the cluster 3510, the CID 3520, and/or the co-driver display 3530 are separated from each other, the present disclosure is not limited thereto. In another embodiment, two or more selected from the cluster 3510, the CID 3520, and the co-driver display 3530 may be integrally connected.

In an embodiment, the vehicle display device 1000F may include a button 3540 that may express preset images. Referring to an enlarged view of FIG. 9H, the button 3540 of a hemispherical shape may include an object 3542 and a display device disposed on the object 3542, wherein the object 3542 provides the feel of a button while moving in the z direction or the -z-direction. In an embodiment, in the case where the object 3542 has a three-dimensionally round surface, the display device may also have a three-dimensionally round surface.

FIG. 12H shows an electronic apparatus according to an embodiment is an electronic apparatus 1000G for advertising or display. In an embodiment, the electronic apparatus 1000G for advertising or display may be installed on a fixed structure 3610 such as a wall or pole. In the case where the structure 3610 includes an uneven surface as shown in FIG. 12H, the electronic apparatus 1000G for advertising or display may be also disposed along the uneven surface of the structure 3610. In an embodiment, the electronic apparatus 1000G for advertising or display may be installed on the structure 3610 using a heat shrink film.

FIG. 12I shows an electronic apparatus 1000H according to an embodiment is a controller. The controller may include an image-type button. As an example, the controller may include first to third button regions 3720, 3730, and 3740 in which a portion of the display portion 3710 protrudes in the z direction or protrudes in the -z direction (or is recessed in the z direction). In an embodiment, the first and third button regions 3720 and 3740 may protrude in the z direction, and the second button region 3730 may protrude in the -z direction (or be recessed in the z direction).

According to an embodiment of the present disclosure, a display device that efficiently utilizes a space, may implement images of an excellent quality, and/or is stretchable may be provided. The above effect is provided as an example, and the effect of the present disclosure is not limited thereto.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display device comprising:
a substrate;
an organic insulating layer disposed on the substrate;
a light-emitting diode including a pixel electrode disposed on the organic insulating layer, an intermediate layer on the pixel electrode, and an opposite electrode on the intermediate layer;
a bank layer disposed on the pixel electrode of the light-emitting diode, the bank layer including a first layer including metal and a second layer disposed on the first layer; and
an inorganic layer disposed between the organic insulating layer and the bank layer,
wherein the bank layer defines therein a first opening and a second opening passing through the first layer and the second layer of the bank layer, the first opening overlaps the pixel electrode in a plan view, and the second opening at least partially surrounds the first opening in the plan view,
wherein the second layer of the bank layer includes a first protrusion tip extending from a point at which a lateral surface of the first layer facing the second opening meets a bottom surface of the second layer,
wherein the organic insulating layer defines therein a concave portion overlapping the second opening in the plan view, and
wherein the inorganic layer includes a second protrusion tip extending from a point at which a lateral surface of the organic insulating layer facing the concave portion meets a bottom surface of the inorganic layer.

2. The display device of claim 1, wherein a length of the second protrusion tip is less than a length of the first protrusion tip.

3. The display device of claim 1, further comprising a dummy opposite electrode including a same material as the opposite electrode,
wherein the opposite electrode is disposed in the first opening of the bank layer and is in direct contact with the first layer of the bank layer, and
wherein the dummy opposite electrode is in direct contact with the first layer of the bank layer while continuously extending within the second opening of the bank layer.

4. The display device of claim 3, further comprising a dummy intermediate layer including a same material as the intermediate layer,
wherein a portion of the dummy intermediate layer is in the concave portion of the organic insulating layer and is covered by the dummy opposite electrode.

5. The display device of claim 1, wherein the second layer of the bank layer includes a third protrusion tip extending from a point at which a lateral surface of the first layer facing the first opening meets the bottom surface of the second layer.

6. The display device of claim 1, wherein the inorganic layer includes an insulating inorganic material.

7. The display device of claim 1, wherein the inorganic layer includes a conductive inorganic material, and the first layer of the bank layer is in direct contact with the conductive inorganic material.

8. The display device of claim 1, wherein the second layer of the bank layer includes an inorganic material.

9. The display device of claim 1, further comprising an encapsulation layer disposed on the light-emitting diode, wherein the encapsulation layer includes an inorganic encapsulation layer including an inorganic insulating material, and the inorganic encapsulation layer covers an upper surface and a lower surface of the first protrusion tip, and an upper surface and a lower surface of the second protrusion tip.

10. The display device of claim 1, wherein a depth of the concave portion is less than a thickness of the first layer of the bank layer, and less than a thickness of the organic insulating layer.

11. An electronic apparatus including a display device, which displays an image, wherein the display device comprises:
a substrate;
an organic insulating layer disposed on the substrate;
a light-emitting diode including a pixel electrode disposed on the organic insulating layer, an intermediate layer on the pixel electrode, and an opposite electrode on the intermediate layer;
a bank layer disposed on the pixel electrode of the light-emitting diode, the bank layer including a first layer including metal and a second layer disposed on the first layer; and
an inorganic layer disposed between the organic insulating layer and the bank layer,
wherein the bank layer defines therein a first opening and a second opening passing through the first layer and the second layer of the bank layer, the first opening overlaps the pixel electrode in a plan view, the second opening at least partially surrounds the first opening in the plan view,
wherein the second layer of the bank layer includes a first protrusion tip extending from a point at which a lateral surface of the first layer facing the second opening meets a bottom surface of the second layer,
wherein the organic insulating layer defines therein a concave portion overlapping the second opening in the plan view, and
wherein the inorganic layer includes a second protrusion tip extending from a point at which a lateral surface of the organic insulating layer facing the concave portion meets a bottom surface of the inorganic layer.

12. The electronic apparatus of claim 11, wherein a depth of the concave portion is less than a thickness of first layer of the bank layer and less than a thickness of the organic insulating layer, and a length of the second protrusion tip is less than a length of the first protrusion tip.

13. The electronic apparatus of claim 11, wherein
the display device further includes a dummy opposite electrode including a same material as the opposite electrode, wherein the opposite electrode is disposed in the first opening of the bank layer and is in direct contact with the first layer of the bank layer, and the dummy opposite electrode is in direct contact with the first layer of the bank layer while continuously extending within the second opening of the bank layer.

14. The electronic apparatus of claim 13, wherein the display device further includes a dummy intermediate layer including a same material as the intermediate layer, and wherein a portion of the dummy intermediate layer is present in the concave portion of the organic insulating layer and is covered by the dummy opposite electrode.

15. The electronic apparatus of claim 11, wherein the second layer of the bank layer includes a third protrusion tip extending from a point at which a lateral surface of the first layer facing the first opening meets the bottom surface of the second layer.

16. The electronic apparatus of claim 11, wherein the inorganic layer includes an insulating inorganic material.

17. The electronic apparatus of claim 11, wherein the inorganic layer includes a conductive inorganic material, and the first layer of the bank layer is in direct contact with the conductive inorganic material.

18. The electronic apparatus of claim 11, wherein the second layer of the bank layer includes an inorganic material.

19. The electronic apparatus of claim 11, wherein the display device further includes an encapsulation layer disposed on the light-emitting diode, and wherein the encapsulation layer includes an inorganic encapsulation layer including an inorganic insulating material, and the inorganic encapsulation layer covers an upper surface and a lower surface of the first protrusion tip, and an upper surface and a lower surface of the second protrusion tip.

20. The electronic apparatus of claim 11, further comprising strokes disposed on a rear surface of the display device and which induces three-dimensional deformation of the display device.
